(19) United States
(12) Patent Application Publication
(10) Pub. No.: US 2025/0102285 A1
(43) Pub. Date: Mar. 27, 2025

(54) DETECTION DEVICE, AND DETECTION METHOD

(71) Applicants: Sumitomo Electric Industries, Ltd., Osaka-shi, Osaka (JP); Sumitomo Wiring Systems, Ltd., Yokkaichi-shi, Mie (JP); AutoNetworks Technologies, Ltd., Yokkaichi-shi, Mie (JP)

(72) Inventors: Masato IZAWA, Osaka-shi, Osaka (JP); Isao KATO, Osaka-shi, Osaka (JP); Hirokazu KOMORI, Osaka-shi, Osaka (JP); Takumi OOSHIMA, Kanuma-shi, Tochigi (JP)

(73) Assignees: Sumitomo Electric Industries, Ltd., Osaka-shi, Osaka (JP); Sumitomo Wiring Systems, Ltd., Yokkaichi-shi, Mie (JP); AutoNetworks Technologies, Ltd., Yokkaichi-shi, Mie (JP)

(21) Appl. No.: 18/730,798

(22) PCT Filed: Jan. 20, 2023
(86) PCT No.: PCT/JP2023/001602

§ 371 Date: Jul. 22, 2024

(30) Foreign Application Priority Data
Jan. 28, 2022 (JP) 2022-011591

(51) Int. Cl. G01B 7/16

(52) U.S. Cl. CPC G01B 7/18

(57) ABSTRACT

A detection device includes: a signal output unit configured to output a measurement signal having a frequency component to a target line; a measurement unit configured to receive, from the target line, a response signal including a signal in which the measurement signal is reflected, and measure at least one of an amplitude and a phase of the received response signal; and a detection unit configured to calculate an evaluation value based on a measurement result obtained by the measurement unit, and detect a change in a level of bending of the target line, based on a change over time in the calculated evaluation value.

### TECHNICAL FIELD

The present invention relates to a detection device and a detection method.

This application claims priority on Japanese Patent Application No. 2022-11591 filed on Jan. 28, 2022, the entire content of which is incorporated herein by reference.

### BACKGROUND ART

PATENT LITERATURE 1 (Japanese Laid-Open Patent Publication No. 2007-305478) discloses an electric cable breakage detection device as follows. That is, the electric cable breakage detection device includes: an electric cable composed of a plurality of electric wires, an electrical shield layer covering the plurality of electric wires, and a sheath covering the electrical shield layer; a breakage detection wire that is provided on the electrical shield layer and includes a conductor wire and an insulating layer on the outer periphery of the conductor wire; a voltage source electrically connected to the conductor wire; a first detector electrically connected to the conductor wire; and a second detector electrically connected to the electrical shield layer.

### CITATION LIST

### Patent Literature

PATENT LITERATURE 1: Japanese Laid-Open Patent Publication No. 2007-305478

### SUMMARY OF THE INVENTION

A detection device according to the present disclosure includes: a signal output unit configured to output a measurement signal having a frequency component to a target line; a measurement unit configured to receive, from the target line, a response signal including a signal in which the measurement signal is reflected, and measure at least one of an amplitude and a phase of the received response signal; and a detection unit configured to calculate an evaluation value based on a measurement result obtained by the measurement unit, and detect a change in a level of bending of the target line, based on a change over time in the calculated evaluation value.

A detection method according to the present disclosure is a detection method in a detection device, and includes: outputting a measurement signal having a frequency component to a target line; receiving, from the target line, a response signal including a signal in which the measurement signal is reflected, and measuring at least one of an amplitude and a phase of the received response signal; and calculating an evaluation value based on a measurement result of at least one of the amplitude and the phase, and detecting a change in a level of bending of the target line, based on a change over time in the calculated evaluation value.

An aspect of the present disclosure can be realized not only as a detection device including such a characteristic processing unit, but also as a program for causing a computer to execute steps of such characteristic processing, as a semiconductor integrated circuit that realizes a part or the entirety of the detection device, or as a system that includes the detection device.

### BRIEF DESCRIPTION OF DRAWINGS

FIG. 1 shows a configuration of a communication system according to a first embodiment of the present disclosure.

FIG. 2 shows an example of a transmission line used in the communication system according to the first embodiment of the present disclosure.

FIG. 3 shows an example of a transmission line used in the communication system according to the first embodiment of the present disclosure.

FIG. 4 shows a configuration of a relay device according to the first embodiment of the present disclosure.

FIG. 5 shows an example of a transmission line used in the communication system according to the first embodiment of the present disclosure.

FIG. 6 shows an example of a transmission line used in the communication system according to the first embodiment of the present disclosure.

FIG. 7 shows a simulation result of a reactance X calculated by a detection unit in a detection device according to the first embodiment of the present disclosure.

FIG. 8 shows an example of a determination table stored in a storage unit in the detection device according to the first embodiment of the present disclosure.

FIG. 9 shows a simulation result of a reactance X calculated by the detection unit in the detection device according to the first embodiment of the present disclosure.

FIG. 10 shows an example of a determination table stored in the storage unit in the detection device according to the first embodiment of the present disclosure.

FIG. 11 shows a simulation result of a reactance X calculated by the detection unit in the detection device according to the first embodiment of the present disclosure.

FIG. 12 shows a simulation result of a reactance X calculated by the detection unit in the detection device according to the first embodiment of the present disclosure.

FIG. 13 shows a simulation result of a resistance R calculated by the detection unit in the detection device according to the first embodiment of the present disclosure.

FIG. 14 shows an example of a determination table stored in the storage unit in the detection device according to the first embodiment of the present disclosure.

FIG. 15 shows a simulation result of a resistance R calculated by the detection unit in the detection device according to the first embodiment of the present disclosure.

FIG. 16 shows an example of a determination table stored in the storage unit in the detection device according to the first embodiment of the present disclosure.

FIG. 17 shows a simulation result of a resistance R calculated by the detection unit in the detection device according to the first embodiment of the present disclosure.

FIG. 18 shows a simulation result of a resistance R calculated by the detection unit in the detection device according to the first embodiment of the present disclosure.

FIG. 19 shows a simulation result of a phase difference pd calculated by the detection unit in the detection device according to the first embodiment of the present disclosure.

FIG. 20 shows an example of a determination table stored in the storage unit in the detection device according to the first embodiment of the present disclosure.

FIG. 21 shows a simulation result of an absolute value Arc of a reflection coefficient rc calculated by the detection unit in the detection device according to the first embodiment of the present disclosure.

FIG. 22 shows an example of a determination table stored in the storage unit in the detection device according to the first embodiment of the present disclosure.

FIG. 23 is a flowchart showing an example of an operation procedure when the relay device according to the first embodiment of the present disclosure performs a detection process.

FIG. 24 shows a configuration of a relay device according to a second embodiment of the present disclosure.

### DETAILED DESCRIPTION

Conventionally, technologies for predicting breakage of transmission lines have been proposed.

### Problems to be Solved by the Present Disclosure

Beyond the technology described in PATENT LITERATURE 1, there is a demand for a technology capable of checking the state of a transmission line such as the level of bending of the transmission line, by using a simple configuration.

The present disclosure has been made to solve the above-described problem, and an object of the present disclosure is to provide a detection device and a detection method capable of checking the state of a transmission line, by using a simple configuration.

### Effects of the Present Disclosure

According to the present disclosure, the state of a transmission line can be checked by using a simple configuration.

### Description of Embodiments of the Present Disclosure

First, contents of the embodiments of the present disclosure are listed and described.

(1) A detection device according to an embodiment of the present disclosure includes: a signal output unit configured to output a measurement signal having a frequency component to a target line; a measurement unit configured to receive, from the target line, a response signal including a signal in which the measurement signal is reflected, and measure at least one of an amplitude and a phase of the received response signal; and a detection unit configured to calculate an evaluation value based on a measurement result obtained by the measurement unit, and detect a change in a level of bending of the target line, based on a change over time in the calculated evaluation value.

As described above, the measurement signal having the frequency component is outputted to the target line, the evaluation value is calculated based on the measurement result of at least one of the amplitude and the phase of the response signal received from the target line, and a change in the level of bending of the target line is detected based on a change over time in the calculated evaluation value. In this configuration, a change in the level of bending of the transmission line that is the target line or the transmission line provided along the target line can be detected without requiring a bending sensor or the like. Therefore, the state of the transmission line can be checked by using a simple configuration.

(2) In the above (1), the detection unit may detect a change in a bending angle of the target line.

In the above configuration, a change in the level of bending of the transmission line can be quantitatively detected as a change in the bending angle, whereby the state of the transmission line can be checked more accurately.

(3) In the above (1) or (2), the detection unit may detect a change in a curvature of the target line.

In the above configuration, a change in the level of bending of the transmission line can be quantitatively detected as a change in the curvature, whereby the state of the transmission line can be checked more accurately.

(4) In any one of the above (1) to (3), the target line may be a transmission line, and the detection unit may calculate, as the evaluation value, at least one of: a phase difference between the measurement signal and the response signal; a reflection coefficient that is a ratio of an amplitude of the response signal to an amplitude of the measurement signal; an impedance of the transmission line; and a resistance of the transmission line.

In the above configuration, as compared to a configuration in which a DC resistance value of a transmission line is calculated as an evaluation value, it is possible to more accurately detect a change in the level of bending of the transmission line, based on the evaluation value that is more greatly changed according to a change in the cross-sectional shape or the like with bending of the transmission line. In addition, for example, the measurement signal is outputted to a transmission line for communication whose terminal ends are matched, and the evaluation value can be calculated based on the measurement result of at least one of the amplitude and the phase of the response signal received from the transmission line. Therefore, a change in the level of bending of the transmission line can be detected without requiring a detection line other than the transmission line.

(5) In any one of the above (1) to (3), the target line may be a transmission line, and the detection unit may calculate, as the evaluation value, a reactance of the transmission line.

As the value of the reactance is more greatly changed according to a change in the cross-sectional shape or the like of the transmission line due to bending of the transmission line, the above configuration enables more accurate detection of the level of bending of the transmission line. Moreover, the measurement signal is outputted to a transmission line for communication whose terminal ends are matched, and the evaluation value can be calculated based on the measurement result of at least one of the amplitude and the phase of the response signal received from the transmission line. Therefore, a change in the level of bending of the transmission line can be detected without requiring a detection line other than the transmission line.

(6) In any one of the above (1) to (3), the target line may be a detection line provided along a transmission line, and the detection unit may calculate, as the evaluation value, at least one of: a capacitance of the detection line, an inductance of the detection line, and a characteristic impedance of the detection line.

In the above configuration, as compared to a configuration in which, for example, a DC resistance value of a detection line is calculated as an evaluation value, it is possible to more accurately detect a change in the level of bending of the transmission line, based on the evaluation value that is more greatly changed according to a change in the cross-sectional shape or the like with bending of the detection line.

(7) In any one of the above (1) to (6), the detection unit may count the number of times of bending of the target line, based on a detection result of the change in the level of bending of the target line.

In the above configuration, for example, a transmission line replacement timing or the like can be determined by using the count value of the number of times of bending as an index of the level of fatigue and deterioration of the transmission line.

(8) In the above (7), the detection unit may perform a predetermined notification process when a count value of the number of times of bending exceeds a predetermined value.

In the above configuration, for example, it is possible to urge the user to replace the transmission line before the transmission line is broken due to fatigue and deterioration.

(9) In any one of the above (1) to (8), the detection unit may store a detection result of the change in the level of bending of the target line into a storage unit.

In the above configuration, for example, it is possible to analyze a reason or the like of bending of the transmission line, by using the detection result of the level of bending of the transmission line.

(10) A detection method according to the embodiment of the present disclosure is a detection method in a detection device, and includes: outputting a measurement signal having a frequency component to a target line; receiving, from the target line, a response signal including a signal in which the measurement signal is reflected, and measuring at least one of an amplitude and a phase of the received response signal; and calculating an evaluation value based on a measurement result of at least one of the amplitude and the phase, and detecting a change in a level of bending of the target line, based on a change over time in the calculated evaluation value.

As described above, the measurement signal having the frequency component is outputted to the target line, the evaluation value is calculated based on the measurement result of at least one of the amplitude and the phase of the response signal received from the target line, and a change in the level of bending of the target line is detected based on a change over time in the calculated evaluation value. In this method, a change in the level of bending of the transmission line that is the target line or the transmission line provided along the target line can be detected without requiring a bending sensor or the like. Therefore, the state of the transmission line can be checked by using a simple configuration.

Hereinafter, embodiments of the present disclosure will be described with reference to the drawings. In the drawings, the same or corresponding parts are denoted by the same reference signs, and description thereof is not repeated. At least some parts of the embodiments described below may be combined together as desired.

### [Configuration and Basic Operation]

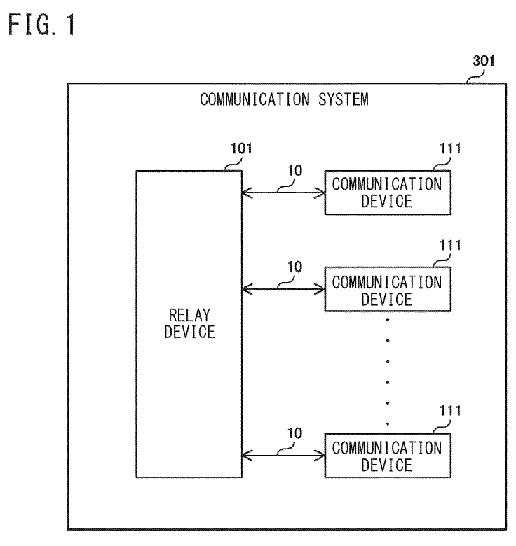

FIG. 1 shows a configuration of a communication system according to a first embodiment of the present disclosure. With reference to FIG. 1, a communication system 301 includes a relay device 101 and a plurality of communication devices 111.

The relay device 101 is connected to each communication device 111 on a one-to-one basis via a transmission line 10 for communication. More specifically, the transmission line 10 includes a cable part, and connector parts provided at a first end and a second end of the cable part. The connector part provided at the first end of the cable part is connected to the relay device 101. The connector part provided at the second end of the cable part is connected to the communication device 111. The transmission line 10 is, for example, an Ethernet (registered trademark) cable.

The communication system 301 is installed in a vehicle, for example. In this case, the communication device 111 is an in-vehicle ECU (Electronic Control Unit), for example. The communication system 301 may be used in a home network or factory automation, for example.

The relay device 101 is capable of communicating with the communication devices 111. The relay device 101 performs, for example, a relay process of relaying information being exchanged between the plurality of communication devices 111 connected to different transmission lines 10. In addition, the relay device 101 functions as a detection device, and performs a detection process of detecting the level of bending of each transmission line 10.

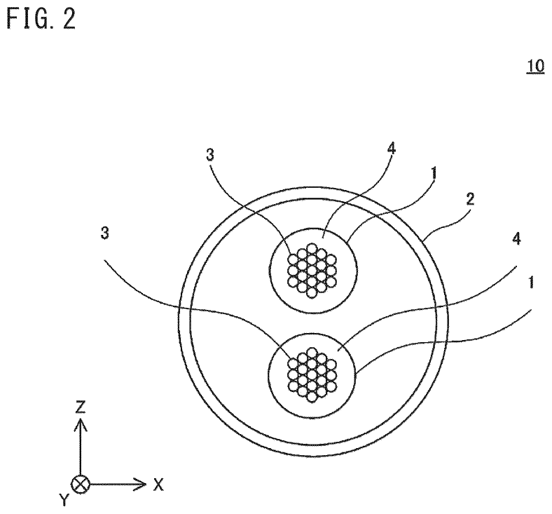

FIG. 2 shows an example of a transmission line used in the communication system according to the first embodiment of the present disclosure. FIG. 2 shows a cross-sectional view of the transmission line 10.

With reference to FIG. 2, the transmission line 10 includes two core wires 1 and a sheath 2. A space between the core wires 1 and the sheath 2 may be filled with an insulator. For example, one of the two core wires 1 is a signal line, and the other is a ground line. For example, the transmission line 10 is a parallel line. That is, the two core wires 1 are arranged parallel to each other. Hereinafter, the length direction of the transmission line 10 is the Y direction, the arrangement direction of the core wires 1 in the cross section of the transmission line 10 is the Z direction, and the direction orthogonal to the Y direction and the Z direction is the X direction.

The transmission line 10 may include one core wire 1 or three or more core wires 1, or may be a twisted pair cable in which a plurality of core wires 1 are twisted together.

In the core wire 1, a plurality of strands 3 are bundled. More specifically, the core wire 1 includes a plurality of strands 3, and an insulating layer 4 that covers the plurality of strands 3. The plurality of strands 3 in the core wire 1 are electrically conducted with each other in the cable part of the transmission line 10. The plurality of strands 3 in the core wire 1 may be coated with, for example, enamel resin or the like so as to be insulated from each other in the cable part of the transmission line 10.

For example, the transmission line 10 has an outer diameter of 3.8 mm, each core wire 1 has an outer diameter of 1.45 mm, each strand 3 has an outer diameter of 0.19 mm, the bundle of the strands 3 in the core wire 1 has an outer diameter of 0.95 mm, and a distance between the two core wires 1 is 0.5 mm.

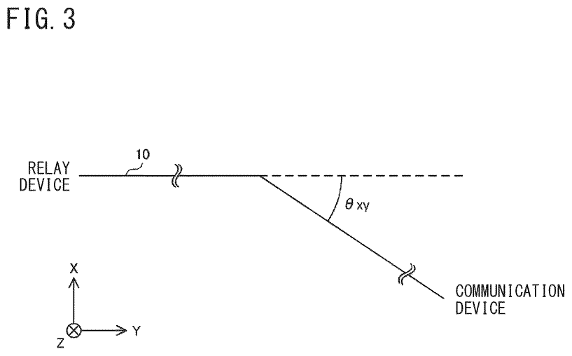

FIG. 3 shows an example of the transmission line used in the communication system according to the first embodiment of the present disclosure. FIG. 3 shows a state where the transmission line 10 is bent in the XY plane. With reference to FIG. 3, the transmission line 10 may be laid while being bent, in the communication system 301. In operating the communication system 301, the transmission line 10 may be bent in the XY plane or the YZ plane due to, for example, external force applied thereto. Hereinafter, a bending angle θ of the transmission line 10 in the XY plane is referred to as a bending angle θxy, and a bending angle θ of the transmission line 10 in the YZ plane is referred to as a bending angle θyz. The bending angle θ is an example of the bending angle of the transmission line 10.

### [Relay Device]

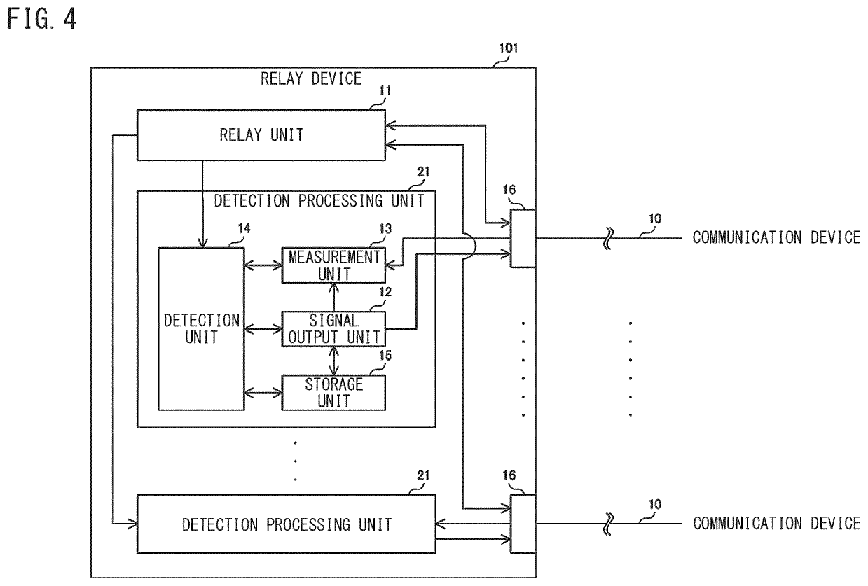

FIG. 4 shows the configuration of the relay device according to the first embodiment of the present disclosure. With reference to FIG. 4, the relay device 101 includes a relay unit 11, a plurality of detection processing units 21, and a plurality of communication ports 16. Each detection processing unit 21 includes a signal output unit 12, a measurement unit 13, a detection unit 14, and a storage unit 15. Some or all of the relay unit 11, the signal output unit 12, the measurement unit 13, and the detection unit 14 are realized by, for example, processing circuitry including one or more processors. The storage unit 15 is, for example, a non-volatile memory included in the processing circuitry. Each communication port 16 is, for example, a connector or a terminal. The connector part of the transmission line 10 is connected to each communication port 16.

For example, an end of the transmission line 10 on the communication device 111 side is impedance-matched. The end of the transmission line 10 need not be accurately impedance-matched.

The relay device 101 outputs a measurement signal having a frequency component to the transmission line 10, and receives, from the transmission line 10, a response signal including a signal in which the measurement signal is reflected. The relay device 101 measures an amplitude and a phase of the received response signal, and calculates an evaluation value EV based on the measurement result. Then, based on a change over time in the calculated evaluation value EV, the relay device 101 detects a change in the level of bending of the transmission line 10. The transmission line 10 is an example of a target line. Details of the processing in the relay device 101 will be described later.

### <Relay Unit>

The relay unit 11 performs a relay process of relaying frames between the communication devices 111. More specifically, the relay unit 11 transmits a frame that has been received from a certain communication device 111 via the corresponding transmission line 10 and the corresponding communication port 16, to another communication device 111 via the corresponding communication port 16 and the corresponding transmission line 10, according to destination information such as a destination IP address, a MAC address, a message ID, etc., of the frame. That is, the relay unit 11 transmits and receives a communication signal including a frame to and from the communication device 111 via the communication port 16 and the transmission line 10.

### <Detection Processing Unit>

For example, the relay device 101 includes the same number of detection processing units 21 as the number of the communication ports 16. More specifically, a detection processing unit 21 is provided so as to correspond to a communication port 16, and performs a detection process of detecting a change in the level of bending of a transmission line 10 connected to the corresponding communication port 16. Hereinafter, the detection process to be performed by one detection processing unit 21 in the relay device 101 will be described as a representative example. A transmission line 10 to be subjected to the detection process of the detection processing unit 21 is also referred to as “target transmission line”.

### (Signal Output Unit)

The signal output unit 12 outputs a measurement signal having a frequency component to the target transmission line. More specifically, the signal output unit 12 outputs an AC signal, a pulse signal, or a frequency sweep signal, as the measurement signal to the target transmission line.

The signal output unit 12 outputs a measurement signal, which has a frequency band different from the frequency band of the communication signal transmitted and received by the relay unit 11 via the target transmission line, to the target transmission line via the corresponding communication port 16. That is, the relay device 101 subjects the communication signal and the measurement signal to frequency division multiplexing.

More specifically, for example, during a detection period T1 in which the power source of the relay device 101 is ON, the signal output unit 12 outputs the measurement signal to the target transmission line via the corresponding communication port 16.

For example, the storage unit 15 has, stored therein, digital signals Ds1 whose number of samples is N and which are obtained by subjecting one cycle of sine wave to digital conversion. Nis an integer not less than 2.

During the detection period T1, the signal output unit 12 continuously outputs the measurement signal to the target transmission line by repeatedly using the N digital signals Ds1 corresponding to one cycle of sine wave in the storage unit 15. More specifically, the signal output unit 12 includes a DA (Digital to Analog) converter. The signal output unit 12 acquires the digital signal Ds1 from the storage unit 15 at an output timing according to the cycle of an operation clock of the DA converter, and outputs a measurement signal, which is generated by converting the digital signal Ds1 into an analog signal by using the DA converter, to the target transmission line via the communication port 16. In addition, the signal output unit 12 outputs the digital signal Ds1 acquired from the storage unit 15 at the output timing, to the detection unit 14 and the measurement unit 13.

The signal output unit 12 may include, for example, a signal generator such as a DDS (Direct Digital Synthesizer), and may output a sine wave generated by the signal generator to the target transmission line via the communication port 16.

### (Measurement Unit)

The measurement unit 13 receives, from the target transmission line, a response signal including a signal in which the measurement signal is reflected, and measures an amplitude and a phase of the received response signal. For example, the measurement unit 13 receives, from the target transmission line via the corresponding communication port 16, the response signal including the measurement signal outputted from the signal output unit 12 and a reflection signal in which the measurement signal is reflected.

More specifically, during the detection period T1, the measurement unit 13 receives the response signal from the target transmission line via the corresponding communication port 16.

The measurement unit 13 includes an AD (Analog to Digital) converter. During the detection period T1, the measurement unit 13 samples the response signal received from the target transmission line, by using the AD converter, to generate a digital signal Ds2 for each sampling timing.

For example, each time the measurement unit 13 generates the digital signal Ds2, the measurement unit 13 subtracts the component of the digital signal Ds1 received from the signal output unit 12, from the generated digital signal Ds2, to generate a digital signal Ds3 indicating the reflection signal.

Based on the generated digital signal Ds3, the measurement unit 13 generates amplitude data Ds3a indicating the amplitude of the reflection signal, and phase data Ds3p indicating the phase of the reflection signal, and outputs the generated amplitude data Ds3a and phase data Ds3p to the detection unit 14.

### (Detection Unit)

The detection unit 14 calculates an evaluation value EV based on a result of measurement by the measurement unit 13, and detects a change in the level of bending of the target transmission line, based on a change over time in the calculated evaluation value EV.

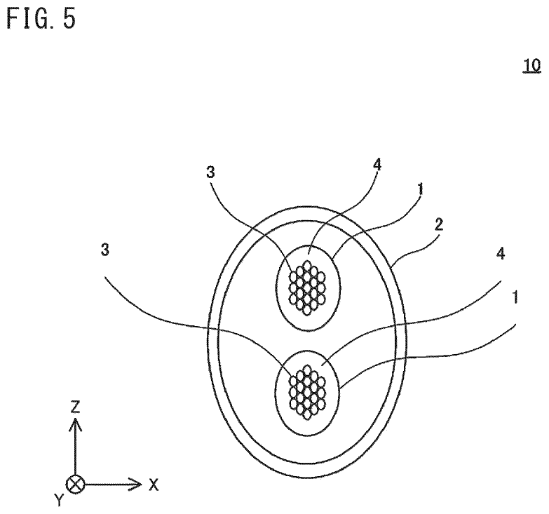

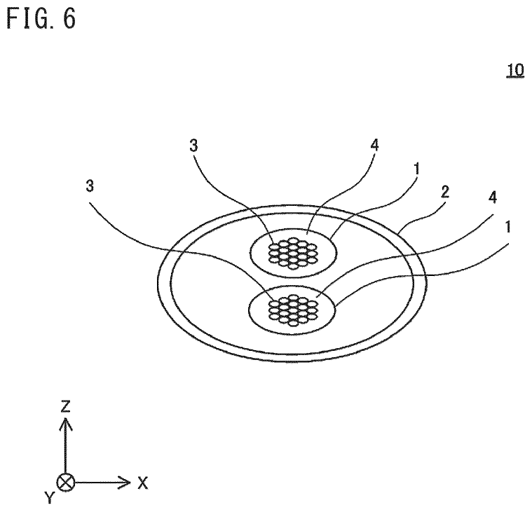

FIG. 5 and FIG. 6 show an example of a transmission line used in the communication system according to the first embodiment of the present disclosure. FIG. 5 shows a cross section of the transmission line 10 in the state of being bent in the XY plane. FIG. 6 shows a cross section of the transmission line 10 in the state of being bent in the YZ plane.

With reference to FIG. 2, FIG. 5, and FIG. 6, if the level of bending of the transmission line 10 in the XY plane or the YZ plane is changed, the distance between the center positions of the adjacent core wires 1, the cross-sectional area and cross-sectional shape of the core wires 1, and the cross-sectional area and cross-sectional shape of the strands 3 are changed, whereby the electrical characteristics of the transmission line 10 are changed.

The detection unit 14 detects a change in the level of bending of the target transmission line, based on a change over time of the electrical characteristics of the target transmission line.

### Detection Example 1

### (1) Bending Angle

The detection unit 14 calculates a reactance X of the target transmission line, as an evaluation value EV. Based on the calculated reactance X, the detection unit 14 detects a change in a bending angle θ of the target transmission line.

More specifically, the signal output unit 12 outputs the measurement signal to the target transmission line, and outputs the digital signal Ds1 corresponding to the outputted measurement signal to the detection unit 14.

Upon receiving the digital signal Ds1 from the signal output unit 12, the detection unit 14 generates amplitude data Ds1a indicating the amplitude of the measurement signal, based on the received digital signal Ds1. The detection unit 14 calculates, for each cycle of the measurement signal, a value obtained by dividing the amplitude data Ds3a received from the measurement unit 13 by the generated amplitude data Ds1a.

The detection unit 14 calculates a reflection coefficient rc, based on the value for each cycle of the measurement signal. Then, the detection unit 14 calculates an impedance Z according to the following formula (1).

$$\begin{matrix}[ Math . 1 ] & \\ Z = \frac{1 + rc}{1 - rc} \times Zout & ( 1 )\end{matrix}$$

In formula (1), Zout is an output impedance of the relay device 101. For example, the output impedance Zout is stored in the storage unit 15 in advance.

After calculating the reflection coefficient rc, the detection unit 14 acquires the output impedance Zout from the storage unit 15, and calculates the impedance Z according to formula (1). Then, the detection unit 14 acquires a reactance X which is an imaginary part of the impedance Z.

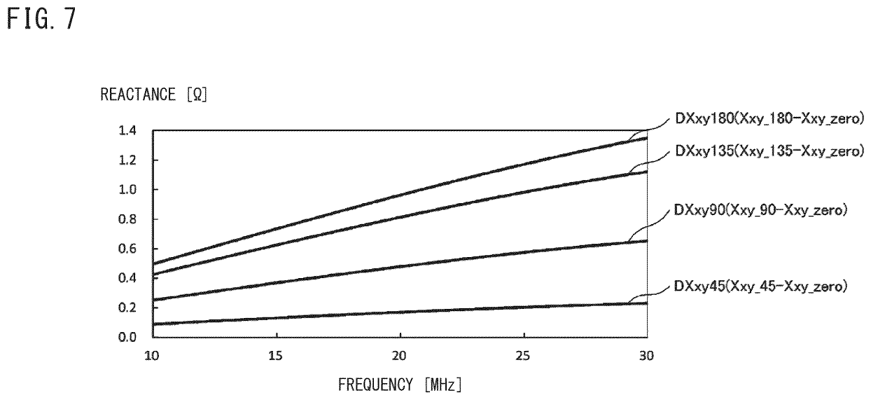

FIG. 7 shows a simulation result of a reactance X calculated by the detection unit in the detection device according to the first embodiment of the present disclosure. FIG. 7 shows a simulation result of a reactance Xxy which is the reactance X calculated by the detection unit 14 when the measurement signal is outputted to a 500 mm transmission line 10 which is bent in the XY plane as shown in FIG. 5 and has a curvature radius Rc of 10 mm at a bent portion. In FIG. 7, the horizontal axis indicates the frequency [MHz] of the measurement signal, and the vertical axis indicates the reactance [2]. FIG. 7 shows a difference DXxy45 obtained by subtracting a reactance Xxy_zero from a reactance Xxy_45, a difference DXxy90 obtained by subtracting the reactance Xxy_zero from a reactance Xxy_90, a difference DXxy135 obtained by subtracting the reactance Xxy_zero from a reactance Xxy_135, and a difference DXxy180 obtained by subtracting the reactance Xxy_zero from a reactance Xxy_180. Here, the reactance Xxy_zero is a reactance Xxy which is calculated by the detection unit 14 when the measurement signal is outputted to a transmission line 10 whose bending angle θxy is zero degrees. The reactance Xxy_45 is a reactance Xxy which is calculated by the detection unit 14 when the measurement signal is outputted to the transmission line 10 whose bending angle θxy is 45 degrees. The reactance Xxy_90 is a reactance Xxy which is calculated by the detection unit 14 when the measurement signal is outputted to a transmission line 10 whose bending angle θxy is 90 degrees. The reactance Xxy_135 is a reactance Xxy which is calculated by the detection unit 14 when the measurement signal is outputted to a transmission line 10 whose bending angle θxy is 135 degrees. The reactance Xxy_180 is a reactance Xxy which is calculated by the detection unit 14 when the measurement signal is outputted to a transmission line 10 whose bending angle θxy is 180 degrees.

With reference to FIG. 7, the differences DXxy180, DXxy135, DXxy90, DXxy45 are arranged in descending order, and are all positive values. That is, the reactance Xxy_180 calculated when the bending angle θxy is 180 degrees, the reactance Xxy_135 calculated when the bending angle θxy is 135 degrees, the reactance Xxy_90 calculated when the bending angle θxy is 90 degrees, the reactance Xxy_45 calculated when the bending angle θxy is 45 degrees, and the reactance Xxy_zero calculated when the bending angle θxy is zero degrees, are arranged in descending order.

According to the simulation result described with reference to FIG. 7, it is possible to detect the bending angle θxy, based on the reactance X.

For example, the storage unit 15 has, stored therein, a reference value SX1 of the reactance X. The reference value SX1 is set in advance based on a reactance X which is calculated by the detection unit 14 when a measurement signal of a specific frequency is outputted to the target transmission line whose bending angle θxy is zero degrees. The reference value SX1 may be set in advance based on a plurality of reactances X which are calculated, when measurement signals of a plurality of specific frequencies are outputted to the target transmission line whose bending angle θxy is zero degrees, by the detection unit 14 for the respective frequencies of the measurement signals.

For example, the detection unit 14 calculates the reactance X at a calculation timing according to a predetermined calculation cycle Cm. The calculation cycle Cm is set to a value shorter than the cycle of bending assumed in the target transmission line, for example, to a value corresponding to the cycle of the measurement signal. Each time the detection unit 14 calculates the reactance X, the detection unit 14 acquires the reference value SX1 from the storage unit 15, and calculates a difference DX1 by subtracting the reference value SX1 from the reactance X.

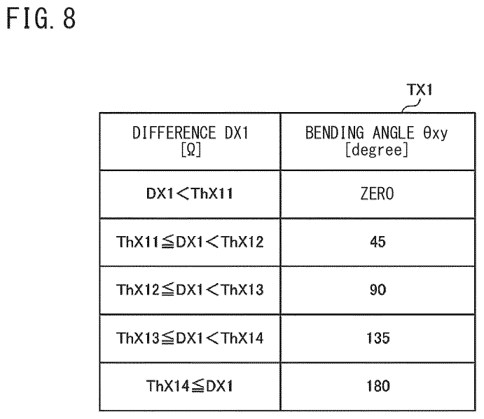

FIG. 8 shows an example of a determination table stored in the storage unit in the detection device according to the first embodiment of the present disclosure. With reference to FIG. 8, the storage unit 15 has, stored therein, a determination table TX1 indicating the correspondence between the difference DX1 calculated by the detection unit 14, and the bending angle θxy.

For example, the detection unit 14 detects the bending angle θxy, based on the calculated difference DX1, and the determination table TX1 stored in the storage unit 15. More specifically, when the difference DX1 is less than a threshold value ThX11, the detection unit 14 determines that the bending angle θxy is zero degrees. When the difference DX1 is equal to or larger than the threshold value ThX11 and less than a threshold value ThX12, the detection unit 14 determines that the bending angle θxy is 45 degrees. When the difference DX1 is equal to or larger than the threshold value ThX12 and less than a threshold value ThX13, the detection unit 14 determines that the bending angle θxy is 90 degrees. When the difference DX1 is equal to or larger than the threshold value ThX13 and less than a threshold value ThX14, the detection unit 14 determines that the bending angle θxy is 135 degrees. When the difference DX1 is equal to or larger than a threshold value ThX14, the detection unit 14 determines that the bending angle θxy is 180 degrees.

For example, the threshold values ThX11, ThX12, ThX13, ThX14 are set in advance based on the above-described reactances Xxy_zero, Xxy_45, Xxy_90, Xxy_135, Xxy_180.

For example, each time the detection unit 14 calculates the difference DX1, the detection unit 14 accumulates the calculated difference DX1 in the storage unit 15 to generate time-series data TSD1 of the difference DX1. Furthermore, for example, the detection unit 14 stores, in the storage unit 15, a detection result of a change in the level of bending of the target transmission line. More specifically, each time the detection unit 14 calculates the difference DX1, the detection unit 14 detects the bending angle θxy based on the calculated difference DX1 and the determination table TX1, and accumulates the detected bending angle θxy in the storage unit 15 to generate time-series data TSDxy of the bending angle θxy.

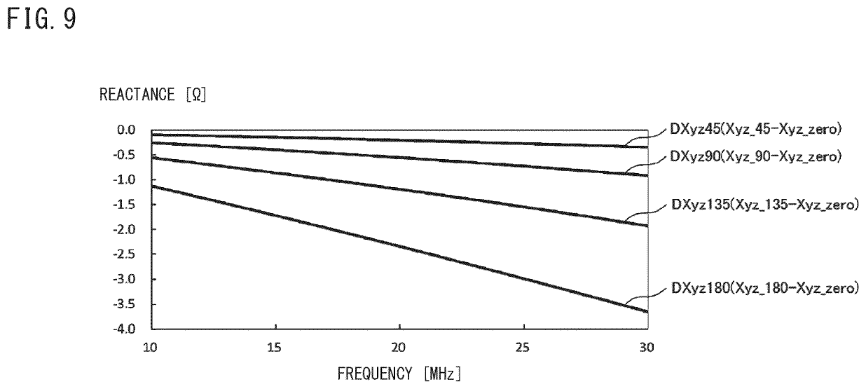

FIG. 9 shows a simulation result of a reactance X calculated by the detection unit in the detection device according to the first embodiment of the present disclosure. FIG. 9 shows a simulation result of a reactance Xyz which is a reactance X calculated by the detection unit 14 when the measurement signal is outputted to a 500 mm transmission line 10 which is bent in the YZ plane as shown in FIG. 6 and has a curvature radius Rc of 10 mm at a bent portion. In FIG. 9, the horizontal axis indicates the frequency [MHz] of the measurement signal, and the vertical axis indicates the reactance [Ω]. FIG. 9 shows a difference DXyz45 obtained by subtracting a reactance Xyz_zero from a reactance Xyz_45, a difference DXyz90 obtained by subtracting the reactance Xyz_zero from a reactance Xyz_90, a difference DXyz135 obtained by subtracting the reactance Xyz_zero from a reactance Xyz_135, and a difference DXyz180 obtained by subtracting the reactance Xyz_zero from a reactance Xyz_180. Here, the reactance Xyz_zero is a reactance Xyz which is calculated by the detection unit 14 when the measurement signal is outputted to the transmission line 10 whose bending angle θyz is zero degrees. The reactance Xyz_45 is a reactance Xyz which is calculated by the detection unit 14 when the measurement signal is outputted to the transmission line 10 whose bending angle θyz is 45 degrees. The reactance Xyz_90 is a reactance Xyz which is calculated by the detection unit 14 when the measurement signal is outputted to the transmission line 10 whose bending angle θyz is 90 degrees. The reactance Xyz_135 is a reactance Xyz which is calculated by the detection unit 14 when the measurement signal is outputted to the transmission line 10 whose bending angle θyz is 135 degrees. The reactance Xyz_180 is a reactance Xyz which is calculated by the detection unit 14 when the measurement signal is outputted to the transmission line 10 whose bending angle θyz is 180 degrees.

With reference to FIG. 9, the differences DXyz45, DXyz90, DXyz135, DXyz180 are arranged in descending order, and are all negative values. That is, the reactance Xxy_zero calculated when the bending angle θyz is zero degrees, the reactance Xyz_45 calculated when the bending angle θyz is 45 degrees, the reactance Xyz_90 calculated when the bending angle θyz is 90 degrees, the reactance Xyz_135 calculated when the bending angle θyz is 135 degrees, and the reactance Xyz_180 calculated when the bending angle θyz is 180 degrees, are arranged in descending order.

According to the simulation result described with reference to FIG. 9, it is possible to detect the bending angle θyz, based on the reactance X.

For example, the storage unit 15 has, stored therein, a reference value SX2 of the reactance X. The reference value SX2 is set in advance based on a reactance X which is calculated by the detection unit 14 when a measurement signal of a specific frequency is outputted to the target transmission line whose bending angle θyz is zero degrees. The reference value SX2 may be set in advance based on a plurality of reactances X which are calculated, when measurement signals of a plurality of specific frequencies are outputted to the target transmission line whose bending angle θyz is zero degrees, by the detection unit 14 for the respective frequencies of the measurement signals. The reference value SX2 may be the same value as the above-described reference value SX1, or may be a different value.

Each time the detection unit 14 calculates the reactance X, the detection unit 14 acquires the reference value SX2 from the storage unit 15, and calculates a difference DX2 by subtracting the reference value SX2 from the reactance X.

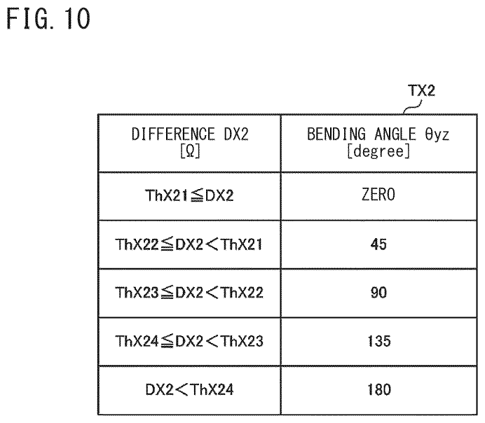

FIG. 10 shows an example of a determination table stored in the storage unit in the detection device according to the first embodiment of the present disclosure. With reference to FIG. 10, the storage unit 15 has, stored therein, a determination table TX2 indicating the correspondence between the difference DX2 calculated by the detection unit 14, and the bending angle θyz.

For example, the detection unit 14 detects the bending angle θyz, based on the calculated difference DX2, and the determination table TX2 stored in the storage unit 15. More specifically, when the difference DX2 is equal to or larger than a threshold value ThX21, the detection unit 14 determines that the bending angle θyz is zero degrees. When the difference DX2 is equal to or larger than a threshold value ThX22 and less than the threshold value ThX21, the detection unit 14 determines that the bending angle θyz is 45 degrees. When the difference DX2 is equal to or larger than a threshold value ThX23 and less than the threshold value ThX22, the detection unit 14 determines that the bending angle θyz is 90 degrees. When the difference DX2 is equal to or larger than a threshold value ThX24 and less than the threshold value ThX23, the detection unit 14 determines that the bending angle θyz is 135 degrees. When the difference DX2 is less than the threshold value ThX24, the detection unit 14 determines that the bending angle θyz is 180 degrees.

For example, the threshold values ThX21, ThX22, ThX23, ThX24 are set in advance based on the above-described reactances Xyz_zero, Xyz_45, Xyz_90, Xyz_135, Xyz_180.

For example, each time the detection unit 14 calculates the difference DX2, the detection unit 14 accumulates the calculated difference DX2 in the storage unit 15 to generate time-series data TSD2 of the difference DX2. Furthermore, for example, each time the detection unit 14 calculates the difference DX2, the detection unit 14 detects the bending angle θyz, based on the calculated difference DX2 and the determination table TX2, and accumulates the detected bending angle θyz in the storage unit 15 to generate time-series data TSDyz of the bending angle θyz.

### (2) Curvature

For example, the detection unit 14 detects a change in the curvature of the target transmission line, based on the reactance X. Here, the curvature of the target transmission line is a reciprocal of the curvature radius Rc.

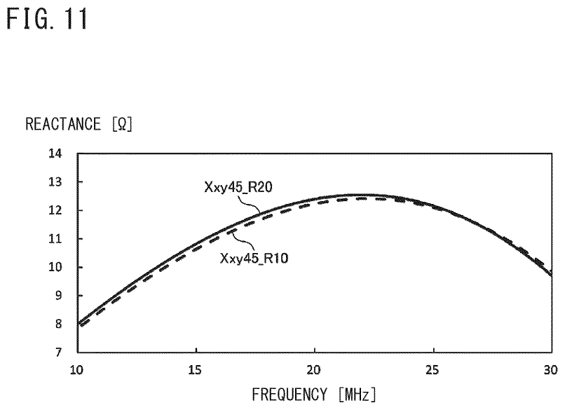

FIG. 11 shows a simulation result of a reactance X calculated by the detection unit in the detection device according to the first embodiment of the present disclosure. FIG. 11 shows a simulation result of a reactance X which is calculated by the detection unit 14 when the measurement signal is outputted to a 1000 mm transmission line 10 which is bent in the XY plane as shown in FIG. 5. In FIG. 11, the horizontal axis indicates the frequency [MHz] of the measurement signal, and the vertical axis indicates the reactance [Ω]. FIG. 11 shows a reactance Xxy45_R10 which is calculated by the detection unit 14 when the measurement signal is outputted to the transmission line 10 whose bending angle θxy is 45 degrees and whose curvature radius Rc is 10 mm, and a reactance Xxy45_R20 which is calculated by the detection unit 14 when the measurement signal is outputted to the transmission line 10 whose bending angle θxy is 45 degrees and whose curvature radius Rc is 20 mm.

With reference to FIG. 11, in the case where the bending angle θxy is 45 degrees, the reactance Xxy45_R10 calculated when the curvature radius Rc is 10 mm and the reactance Xxy45_R20 calculated when the curvature radius Rc is 20 mm are different from each other.

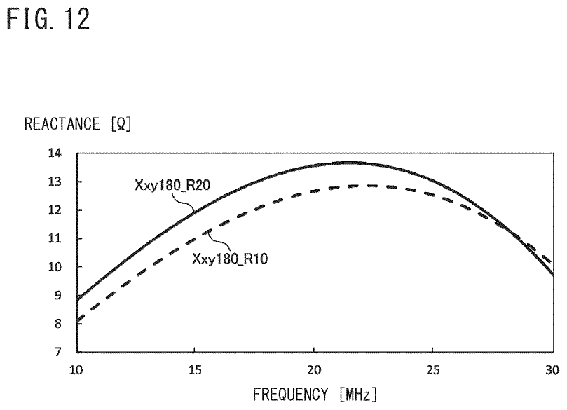

FIG. 12 shows a simulation result of a reactance X calculated by the detection unit in the detection device according to the first embodiment of the present disclosure. FIG. 12 shows a simulation result of a reactance X which is calculated by the detection unit 14 when the measurement signal is outputted to the 1000 mm transmission line 10 which is bent in the XY plane as shown in FIG. 5. In FIG. 12, the horizontal axis indicates the frequency [MHz] of the measurement signal, and the vertical axis indicates the reactance [Ω]. FIG. 12 shows a reactance Xxy180_R10 which is calculated by the detection unit 14 when the measurement signal is outputted to a transmission line 10 whose bending angle θxy is 180 degrees and whose curvature radius Rc is 10 mm, and a reactance Xxy180_R20 which is calculated by the detection unit 14 when the measurement signal is outputted to a transmission line 10 whose bending angle θxy is 180 degrees and whose curvature radius Rc is 20 mm.

With reference to FIG. 12, in the case where the bending angle θxy is 180 degrees, the reactance Xxy180_R10 calculated when the curvature radius Rc is 10 mm and the reactance Xxy180_R20 calculated when the curvature radius Rc is 20 mm are different from each other.

According to the simulation result described with reference to FIG. 11 and FIG. 12, it is possible to detect the curvature radius Rc and the curvature of the target transmission line, based on the reactance X.

For example, it is possible to predict which of the bending angle θ and the curvature of the target transmission line tends to change, according to the initial laying condition of the target transmission line in the communication system 301. The detection unit 14 detects at least one of a change in the bending angle θ of the target transmission line and a change in the curvature of the target transmission line, based on information indicating the initial laying condition of the target transmission line and on the reactance X.

### Detection Example 2

### (1) Bending Angle

The detection unit 14 calculates a resistance R of the target transmission line, as an evaluation value EV. Based on the calculated resistance R, the detection unit 14 detects a change in the bending angle θ of the target transmission line.

More specifically, the detection unit 14 calculates an impedance Z by performing the process described in Detection example 1. Then, the detection unit 14 acquires a resistance R which is a real part of the impedance Z.

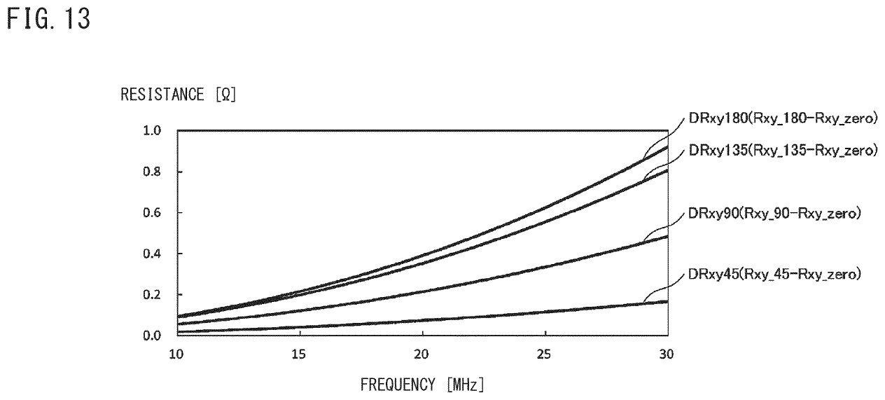

FIG. 13 shows a simulation result of a resistance R calculated by the detection unit in the detection device according to the first embodiment of the present disclosure. FIG. 13 shows a simulation result of a resistance Rxy which is a resistance R calculated by the detection unit 14 when the measurement signal is outputted to a 500 mm transmission line 10 which is bent in the XY plane as shown in FIG. 5 and has a curvature radius Rc of 10 mm at a bent portion. In FIG. 13, the horizontal axis indicates the frequency [MHz] of the measurement signal, and the vertical axis indicates the resistance [Ω]. FIG. 13 shows a difference DRxy45 obtained by subtracting a resistance Rxy_zero from a resistance Rxy_45, a difference DRxy90 obtained by subtracting the resistance Rxy_zero from a resistance Rxy_90, a difference DRxy135 obtained by subtracting the resistance Rxy_zero from the resistance Rxy_135, and a difference DRxy180 obtained by subtracting the resistance Rxy_zero from the resistance Rxy_180. Here, the resistance Rxy_zero is a resistance Rxy which is calculated by the detection unit 14 when the measurement signal is outputted to the transmission line 10 whose bending angle θxy is zero degrees. The resistance Rxy_45 is a resistance Rxy which is calculated by the detection unit 14 when the measurement signal is outputted to the transmission line 10 whose bending angle θxy is 45 degrees. The resistance Rxy_90 is a resistance Rxy which is calculated by the detection unit 14 when the measurement signal is outputted to the transmission line 10 whose bending angle θxy is 90 degrees. The resistance Rxy_135 is a resistance Rxy which is calculated by the detection unit 14 when the measurement signal is outputted to the transmission line 10 whose bending angle θxy is 135 degrees. The resistance Rxy_180 is a resistance Rxy which is calculated by the detection unit 14 when the measurement signal is outputted to the transmission line 10 whose bending angle θxy is 180 degrees.

With reference to FIG. 13, the differences DRxy180, DRxy135, DRxy90, DRxy45 are arranged in descending order, and are all positive values. That is, the resistance Rxy_180 calculated when the bending angle θxy is 180 degrees, the resistance Rxy_135 calculated when the bending angle θxy is 135 degrees, the resistance Rxy_90 calculated when the bending angle θxy is 90 degrees, the resistance Rxy_45 calculated when the bending angle θxy is 45 degrees, and the resistance Rxy_zero calculated when the bending angle θxy is zero degrees, are arranged in descending order.

According to the simulation result described with reference to FIG. 13, it is possible to detect the bending angle θxy, based on the resistance R.

For example, the storage unit 15 has, stored therein, a reference value SR1 of the resistance R. The reference value SR1 is set in advance based on a resistance R which is calculated by the detection unit 14 when a measurement signal of a specific frequency is outputted to the target transmission line whose bending angle θxy is zero degrees. The reference value SR1 may be set in advance based on a plurality of resistances R which are calculated, when measurement signals of a plurality of specific frequencies are outputted to the target transmission line whose bending angle θxy is zero degrees, by the detection unit 14 for the respective frequencies of the measurement signals.

For example, the detection unit 14 calculates the reactance X at a calculation timing according to the calculation cycle Cm. Each time the detection unit 14 calculates the resistance R, the detection unit 14 acquires the reference value SR1 from the storage unit 15, and calculates a difference DR1 by subtracting the reference value SR1 from the resistance R.

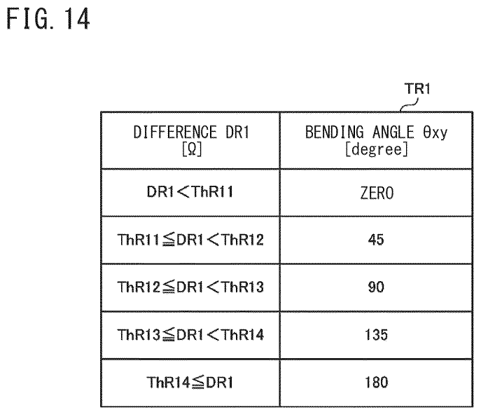

FIG. 14 shows an example of a determination table stored in the storage unit in the detection device according to the first embodiment of the present disclosure. With reference to FIG. 14, the storage unit 15 has, stored therein, a determination table TR1 indicating the correspondence between the difference DR1 calculated by the detection unit 14, and the bending angle θxy.

For example, the detection unit 14 detects the bending angle θxy, based on the calculated difference DR1, and the determination table TR1 stored in the storage unit 15. More specifically, when the difference DR1 is less than a threshold value ThR11, the detection unit 14 determines that the bending angle θxy is zero degrees. When the difference DR1 is equal to or larger than the threshold value ThR11 and less than a threshold value ThR12, the detection unit 14 determines that the bending angle θxy is 45 degrees. When the difference DR1 is equal to or larger than the threshold value ThR12 and less than a threshold value ThR13, the detection unit 14 determines that the bending angle θxy is 90 degrees. When the difference DR1 is equal to or larger than the threshold value ThR13 and less than a threshold value ThR14, the detection unit 14 determines that the bending angle θxy is 135 degrees. When the difference DR1 is equal to or larger than the threshold value ThR14, the detection unit 14 determines that the bending angle θxy is 180 degrees.

For example, the threshold values ThR11, ThR12, ThR13, ThR14 are set in advance based on the above-described resistances Rxy_zero, Rxy_45, Rxy_90, Rxy_135, Rxy_180.

For example, each time the detection unit 14 calculates the difference DR1, the detection unit 14 accumulates the calculated difference DR1 in the storage unit 15 to generate time-series data TSD1 of the difference DR1. Furthermore, for example, each time the detection unit 14 calculates the difference DR1, the detection unit 14 detects the bending angle θxy based on the calculated difference DR1 and the determination table TR1, and accumulates the detected bending angle θxy in the storage unit 15 to generate time-series data TSDxy of the bending angle θxy.

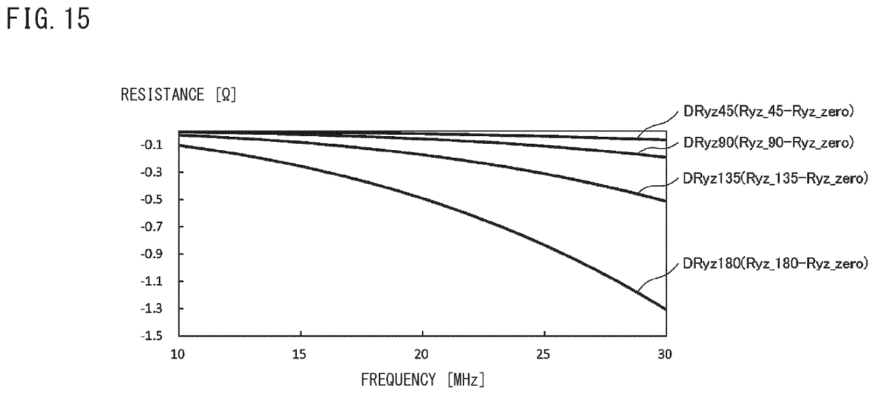

FIG. 15 shows a simulation result of a resistance R calculated by the detection unit in the detection device according to the embodiment of the present disclosure. FIG. 15 shows a simulation result of a resistance Ryz which is a resistance R calculated by the detection unit 14 when the measurement signal is outputted to a 500 mm transmission line 10 which is bent in the YZ plane as shown in FIG. 6 and has a curvature radius Rc of 10 mm at a bent portion. In FIG. 15, the horizontal axis indicates the frequency [MHz] of the measurement signal, and the vertical axis indicates the resistance [Ω]. FIG. 15 shows a difference DRyz45 obtained by subtracting a resistance Ryz_zero from a resistance Ryz_45, a difference DRyz90 obtained by subtracting the resistance Ryz_zero from a resistance Ryz_90, a difference DRyz135 obtained by subtracting the resistance Ryz_zero from a resistance Ryz_135, and a difference DRyz180 obtained by subtracting the resistance Ryz_zero from a resistance Ryz_180. Here, the resistance Ryz_zero is a resistance Ryz which is calculated by the detection unit 14 when the measurement signal is outputted to the transmission line 10 whose bending angle θyz is zero degrees. The resistance Ryz_45 is a resistance Ryz which is calculated by the detection unit 14 when the measurement signal is outputted to the transmission line 10 whose bending angle θyz is 45 degrees. The resistance Ryz_90 is a resistance Ryz which is calculated by the detection unit 14 when the measurement signal is outputted to the transmission line 10 whose bending angle θyz is 90 degrees. The resistance Ryz_135 is a resistance Ryz which is calculated by the detection unit 14 when the measurement signal is outputted to the transmission line 10 whose bending angle θyz is 135 degrees. The resistance Ryz_180 is a resistance Ryz which is calculated by the detection unit 14 when the measurement signal is outputted to the transmission line 10 whose bending angle θyz is 180 degrees.

With reference to FIG. 15, the differences DRyz45, DRyz90, DRyz135, DRyz180 are arranged in descending order, and are all negative values. That is, the resistance Rxy_zero calculated when the bending angle θyz is zero degrees, the resistance Ryz_45 calculated when the bending angle θyz is 45 degrees, the resistance Ryz_90 calculated when the bending angle θyz is 90 degrees, the resistance Ryz_135 calculated when the bending angle θyz is 135 degrees, and the resistance Ryz_180 calculated when the bending angle θyz is 180 degrees, are arranged in descending order.

According to the simulation result described with reference to FIG. 15, it is possible to detect the bending angle θyz, based on the resistance R.

For example, the storage unit 15 has, stored therein, a reference value SR2 of the resistance R. The reference value SR2 is set in advance based on a resistance R which is calculated by the detection unit 14 when a measurement signal of a specific frequency is outputted to the target transmission line whose bending angle θyz is zero degrees. The reference value SR2 may be set in advance based on a plurality of resistances R which are calculated, when measurement signals of a plurality of specific frequencies are outputted to the target transmission line whose bending angle θyz is zero degrees, by the detection unit 14 for the respective frequencies of the measurement signals. The reference value SR2 may be the same value as the above-described reference value SR1, or may be a different value.

After calculating the resistance R, the detection unit 14 acquires the reference value SR2 from the storage unit 15, and calculates a difference DR2 by subtracting the reference value SR2 from the resistance R.

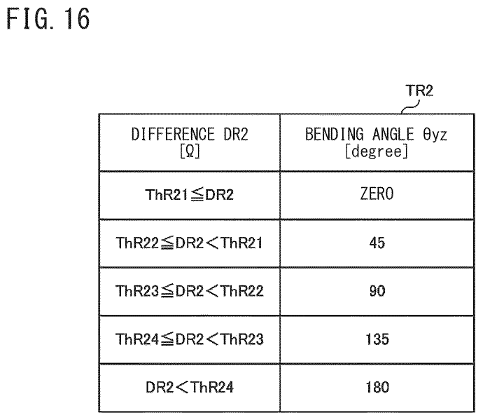

FIG. 16 shows an example of a determination table stored in the storage unit in the detection device according to the first embodiment of the present disclosure. With reference to FIG. 16, the storage unit 15 has, stored therein, a determination table TR2 indicating the correspondence between the difference DR2 calculated by the detection unit 14, and the bending angle θyz.

For example, the detection unit 14 detects the bending angle θyz, based on the calculated difference DR2, and the determination table TR2 stored in the storage unit 15. More specifically, when the difference DR2 is equal to or larger than a threshold value ThR21, the detection unit 14 determines that the bending angle θyz is zero degrees. When the difference DR2 is equal to or larger than a threshold value ThR22 and less than the threshold value ThR21, the detection unit 14 determines that the bending angle θyz is 45 degrees. When the difference DR2 is equal to or larger than a threshold value ThR23 and less than the threshold value ThR22, the detection unit 14 determines that the bending angle θyz is 90 degrees. When the difference DR2 is equal to or larger than a threshold value ThR24 and less than the threshold value ThR23, the detection unit 14 determines that the bending angle θyz is 135 degrees. When the difference DR2 is less than the threshold value ThR24, the detection unit 14 determines that the bending angle θyz is 180 degrees.

For example, the threshold values ThR21, ThR22, ThR23, ThR24 are set in advance based on the above-described resistances Ryz_zero, Ryz_45, Ryz_90, Ryz_135, Ryz_180.

For example, each time the detection unit 14 calculates the difference DR2, the detection unit 14 accumulates the calculated difference DR2 in the storage unit 15 to generate time-series data TSD2 of the difference DR2. Furthermore, for example, each time the detection unit 14 calculates the difference DR2, the detection unit 14 detects the bending angle θyz, based on the calculated difference DR2 and the determination table TR2, and accumulates the detected bending angle θyz in the storage unit 15 to generate time-series data TSDyz of the bending angle θyz.

### (2) Curvature

For example, the detection unit 14 detects a change in the curvature of the target transmission line, based on the resistance R.

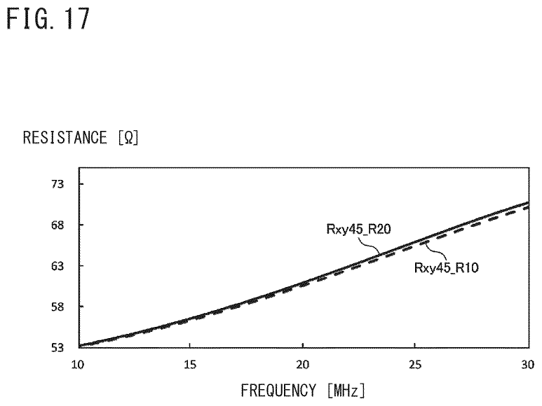

FIG. 17 shows a simulation result of a resistance R calculated by the detection unit in the detection device according to the first embodiment of the present disclosure. FIG. 17 shows a simulation result of a resistance R which is calculated by the detection unit 14 when the measurement signal is outputted to a 1000 mm transmission line 10 which is bent in the XY plane as shown in FIG. 5. In FIG. 17, the horizontal axis indicates the frequency [MHz] of the measurement signal, and the vertical axis indicates the resistance [Ω]. FIG. 17 shows a resistance Rxy45_R10 which is calculated by the detection unit 14 when the measurement signal is outputted to the transmission line 10 whose bending angle θxy is 45 degrees and whose curvature radius Rc is 10 mm, and a resistance Rxy45_R20 which is calculated by the detection unit 14 when the measurement signal is outputted to the transmission line 10 whose bending angle θxy is 45 degrees and whose curvature radius Rc is 20 mm.

With reference to FIG. 17, in the case where the bending angle θxy is 45 degrees, the resistance Rxy45_R10 calculated when the curvature radius Rc is 10 mm and the resistance Rxy45_R20 calculated when the curvature radius Rc is 20 mm are different from each other.

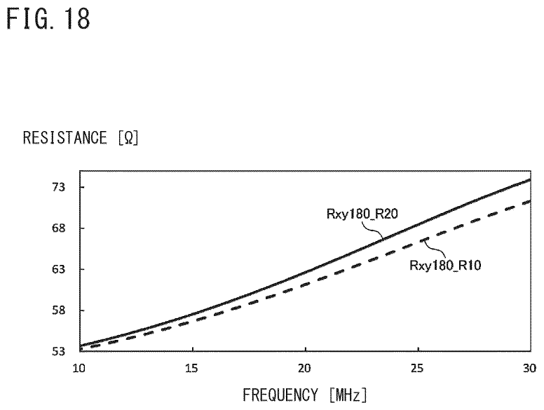

FIG. 18 shows a simulation result of a resistance R calculated by the detection unit in the detection device according to the first embodiment of the present disclosure. FIG. 18 shows a simulation result of a reactance X which is calculated by the detection unit 14 when the measurement signal is outputted to a 1000 mm transmission line 10 which is bent in the XY plane as shown in FIG. 5. In FIG. 18, the horizontal axis indicates the frequency [MHz] of the measurement signal, and the vertical axis indicates the resistance [Ω]. FIG. 18 shows a resistance Rxy_180_R10 which is calculated by the detection unit 14 when the measurement signal is outputted to the transmission line 10 whose bending angle θxy is 180 degrees and whose curvature radius Rc is 10 mm, and a resistance Rxy_180_R20 which is calculated by the detection unit 14 when the measurement signal is outputted to the transmission line 10 whose bending angle θxy is 180 degrees and whose curvature radius Rc is 20 mm.

With reference to FIG. 18, in the case where the bending angle θxy is 180 degrees, the resistance Rxy180_R10 calculated when the curvature radius Rc is 10 mm and the resistance Rxy180_R20 calculated when the curvature radius Rc is 20 mm are different from each other.

According to the simulation result described with reference to FIG. 17 and FIG. 18, it is possible to detect the curvature radius Rc and the curvature of the target transmission line, based on the resistance R.

For example, the detection unit 14 detects at least one of a change in the bending angle θ of the target transmission line and a change in the curvature of the target transmission line, based on information indicating the initial laying condition of the target transmission line and on the resistance R.

### Detection Example 3

### (1) Bending Angle

The detection unit 14 calculates a phase difference between a measurement signal and a response signal, as an evaluation value EV. As an example, the detection unit 14 calculates a phase difference pd between a measurement signal outputted to the target transmission line and a reflection signal included in a response signal. The detection unit 14 detects a bending angle θ of the target transmission line, based on the calculated phase difference pd.

More specifically, the signal output unit 12 outputs the measurement signal to the target transmission line, and outputs a digital signal Ds1 corresponding to the outputted measurement signal, to the detection unit 14.

Upon receiving the digital signal Ds1 from the signal output unit 12, the detection unit 14 generates phase data Ds1p indicating the phase of the measurement signal, based on the received digital signal Ds1. The detection unit 14 calculates a difference between a phase data Ds3p received from the measurement unit 13 and the calculated phase data Ds1p, for each cycle of the measurement signal, for example.

The detection unit 14 calculates the phase difference pd, based on the difference for each cycle of the measurement signal.

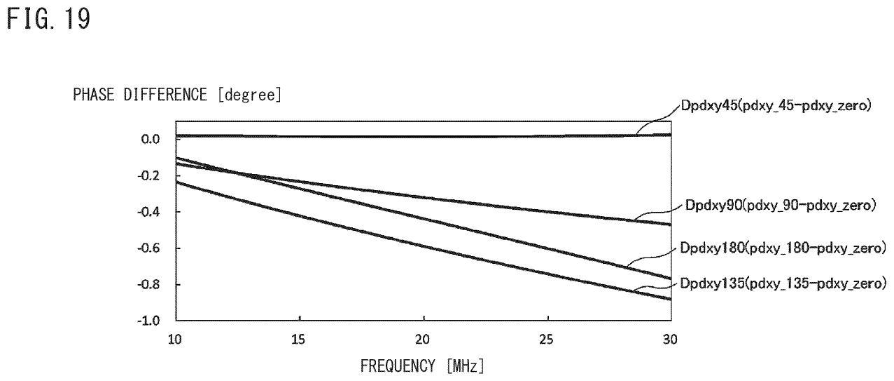

FIG. 19 shows a simulation result of a phase difference pd calculated by the detection unit in the detection device according to the first embodiment of the present disclosure. FIG. 19 shows a simulation result of a phase difference pdxy which is a phase difference pd calculated by the detection unit 14 when the measurement signal is outputted to a transmission line 10 which is bent in the XY plane as shown in FIG. 5 and has a curvature radius Rc of 10 mm at a bent portion. In FIG. 19, the horizontal axis indicates the frequency [MHz] of the measurement signal, and the vertical axis indicates the phase difference [degree]. FIG. 19 shows a difference Dpdxy45 obtained by subtracting a phase difference pdxy_zero from a phase difference pdxy_45, a difference Dpdxy90 obtained by subtracting the phase difference pdxy_zero from a phase difference pdxy_90, a difference Dpdxy135 obtained by subtracting the phase difference pdxy_zero from a phase difference pdxy_135, and a difference Dpdxy180 obtained by subtracting the phase difference pdxy_zero from a phase difference pdxy_180. Here, the phase difference pdxy_zero is a phase difference pdxy which is calculated by the detection unit 14 when the measurement signal is outputted to the transmission line 10 whose bending angle θxy is zero degrees. The phase difference pdxy_45 is a phase difference pdxy which is calculated by the detection unit 14 when the measurement signal is outputted to a transmission line 10 whose bending angle θxy is 45 degrees. The phase difference pdxy_90 is a phase difference pdxy which is calculated by the detection unit 14 when the measurement signal is outputted to the transmission line 10 whose bending angle θxy is 90 degrees. The phase difference pdxy_135 is a phase difference pdxy which is calculated by the detection unit 14 when the measurement signal is outputted to the transmission line 10 whose bending angle θxy is 135 degrees. The phase difference pdxy_180 is a phase difference pdxy which is calculated by the detection unit 14 when the measurement signal is outputted to the transmission line 10 whose bending angle θxy is 180 degrees.

With reference to FIG. 19, for example, when the frequency of the measurement signal is 25 MHz, the differences Dpdxy45, Dpdxy90, Dpdxy180, Dpdxy135 are arranged in descending order. The difference Dpdxy45 is a positive value, and the differences Dpdxy90, Dpdxy180, Dpdxy135 are negative values. That is, the phase difference pdxy_45 calculated when the bending angle θxy is 45 degrees, the phase difference pdxy_zero calculated when the bending angle θxy is zero degrees, the phase difference pdxy_90 calculated when the bending angle θxy is 90 degrees, the phase difference pdxy_180 calculated when the bending angle θ is 180 degrees, and the phase difference pdxy_135 calculated when the bending angle θxy is 135 degrees, are arranged in descending order.

According to the simulation result described with reference to FIG. 19, it is possible to detect the bending angle θxy of the target transmission line, based on the phase difference pd.

For example, the storage unit 15 has, stored therein, a reference value Spd1 of the phase difference pd. The reference value Spd1 is set in advance based on a phase difference pd which is calculated by the detection unit 14 when a measurement signal of a specific frequency is outputted to the target transmission line whose bending angle θxy is zero degrees. The reference value Spd1 may be set in advance based on a plurality of phase differences pd which are calculated, when measurement signals of a plurality of specific frequencies are outputted to the target transmission line whose bending angle θxy is zero degrees, by the detection unit 14 for the respective frequencies of the measurement signals.

For example, the detection unit 14 calculates the phase difference pd at a calculation timing according to the calculation cycle Cm. Each time the detection unit 14 calculates the phase difference pd, the detection unit 14 acquires the reference value Spd1 from the storage unit 15, and calculates a difference Dpd1 by subtracting the reference value Spd1 from the phase difference pd.

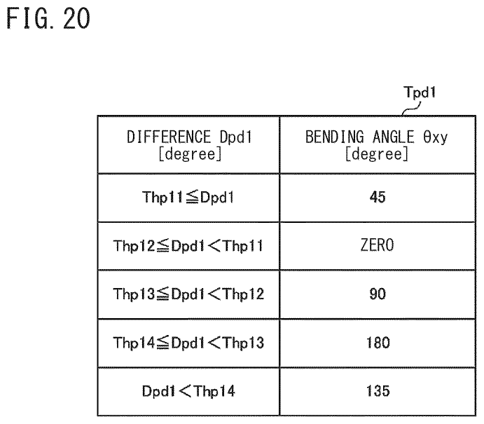

FIG. 20 shows an example of a determination table stored in the storage unit in the detection device according to the first embodiment of the present disclosure. With reference to FIG. 20, the storage unit 15 has, stored therein, a determination table Tpd1 indicating the correspondence between the difference Dpd1 calculated by the detection unit 14, and the bending angle θxy.

For example, the detection unit 14 determines the bending angle θxy of the target transmission line, based on the calculated difference Dpd1, and the determination table Tpd1 stored in the storage unit 15. More specifically, when the difference Dpd1 is equal to or larger than a threshold value Thp11, the detection unit 14 determines that the bending angle θxy is 45 degrees. When the difference Dpd1 is equal to or larger than a threshold value Thp12 and less than the threshold value Thp11, the detection unit 14 determines that the bending angle θxy is zero degrees. When the difference Dpd1 is equal to or larger than a threshold value Thp13 and less than the threshold value Thp12, the detection unit 14 determines that the bending angle θxy is 90 degrees. When the difference Dpd1 is equal to or larger than a threshold value Thp14 and less than the threshold value Thp13, the detection unit 14 determines that the bending angle θxy is 180 degrees. When the difference Dpd1 is less than the threshold value Thp14, the detection unit 14 determines that the bending angle θxy is 135 degrees.

For example, the threshold values Thp11, Thp12, Thp13, Thp14 are set in advance based on the above-described phase differences pdxy_zero, pdxy_45, pdxy_90, pdxy_135, pdxy_180.

For example, each time the detection unit 14 calculates the difference Dpd1, the detection unit 14 accumulates the calculated difference Dpd1 in the storage unit 15 to generate time-series data TSD1 of the difference Dpd1. Furthermore, for example, each time the detection unit 14 calculates the difference Dpd1, the detection unit 14 detects the bending angle θxy based on the calculated difference Dpd1 and the determination table TDpd1, and accumulates the detected bending angle θxy in the storage unit 15 to generate time-series data TSDxy of the bending angle θxy.

For example, the detection unit 14 further performs detection of the bending angle θyz and generation of the time-series data TSDyz, based on the phase difference pd, in the same manner as in Detection example 1 and Detection example 2 described above.

Furthermore, for example, the detection unit 14 detects at least one of a change in the bending angle θ of the target transmission line and a change in the curvature of the target transmission line, based on information indicating the initial laying condition of the target transmission line and on the phase difference pd.

### Detection Example 4

### (1) Bending Angle

The detection unit 14 calculates, as an evaluation value EV, a reflection coefficient which is a ratio of an amplitude of a response signal to an amplitude of a measurement signal. As an example, the detection unit 14 calculates a reflection coefficient rc which is a ratio of an amplitude of a reflection signal to an amplitude of a measurement signal included in a response signal. Based on the calculated reflection coefficient rc, the detection unit 14 detects a change in the bending angle θ of the target transmission line.

More specifically, the detection unit 14 calculates an absolute value Arc of the reflection coefficient rc by performing the process described in Detection example 1.

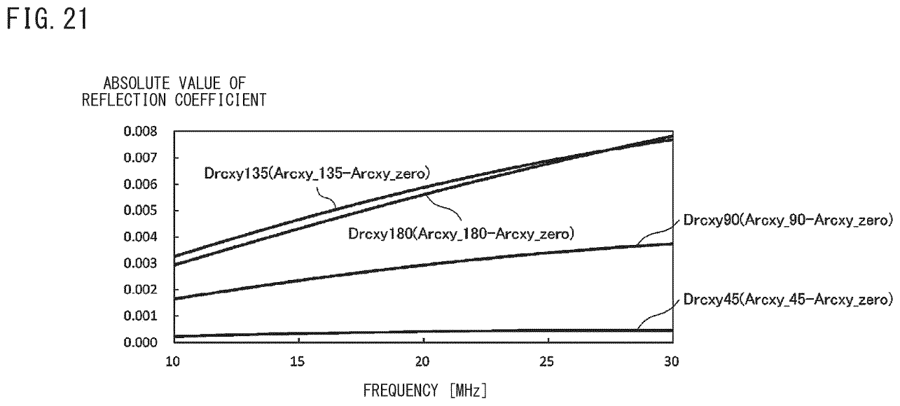

FIG. 21 shows a simulation result of an absolute value Arc of a reflection coefficient rc calculated by the detection unit in the detection device according to the first embodiment of the present disclosure. FIG. 21 shows a simulation result of an absolute value Arcxy which is the absolute value Arc of the reflection coefficient rc calculated by the detection unit 14 when the measurement signal is outputted to a transmission line 10 which is bent in the XY plane as shown in FIG. 5 and has a curvature radius Rc of 10 mm at a bent portion. In FIG. 21, the horizontal axis indicates the frequency [MHz] of the measurement signal, and the vertical axis indicates the absolute value of the reflection coefficient. FIG. 21 shows a difference Drcxy45 obtained by subtracting an absolute value Arcxy_zero from an absolute value Arcxy_45, a difference Droxy90 obtained by subtracting the absolute value Arcxy_zero from an absolute value Arcxy_90, a difference Droxy135 obtained by subtracting the absolute value Arcxy_zero from an absolute value Arcxy_135, and a difference Droxy180 obtained by subtracting the absolute value Arcxy_zero from an absolute value Arcxy_180. Here, the absolute value Arcxy_zero is an absolute value Arcxy of the reflection coefficient rc calculated by the detection unit 14 when the measurement signal is outputted to the transmission line 10 whose bending angle θxy is zero degrees. The absolute value Arcxy_45 is an absolute value Arcxy of the reflection coefficient rc which is calculated by the detection unit 14 when the measurement signal is outputted to the transmission line 10 whose bending angle θxy is 45 degrees. The absolute value Arcxy_90 is an absolute value Arcxy of the reflection coefficient rc calculated by the detection unit 14 when the measurement signal is outputted to the transmission line 10 whose bending angle θxy is 90 degrees. The absolute value Arcxy_135 is an absolute value Arcxy of the reflection coefficient rc calculated by the detection unit 14 when the measurement signal is outputted to the transmission line 10 whose bending angle θxy is 135 degrees. The absolute value Arcxy_180 is an absolute value Arcxy of the reflection coefficient rc which is calculated by the detection unit 14 when the measurement signal is outputted to the transmission line 10 whose bending angle θxy is 180 degrees.

With reference to FIG. 21, for example, in the case where the frequency of the measurement signal is 30 MHz, the differences Drcxy180, Droxy135, Drcxy90, Drcxy45 are arranged in descending order, and are all positive values. That is, the absolute value Arcxy_180 calculated when the bending angle θxy is 180 degrees, the absolute value Arcxy_135 calculated when the bending angle θxy is 135 degrees, the absolute value Arcxy_90 calculated when the bending angle θxy is 90 degrees, the absolute value Arcxy_45 calculated when the bending angle θ is 45 degrees, and the absolute value Arcxy_zero calculated when the bending angle θxy is zero degrees, are arranged in descending order.

According to the simulation result described with reference to FIG. 21, it is possible to detect the bending angle θxy of the target transmission line, based on the absolute value Arcxy of the reflection coefficient rc.

For example, the storage unit 15 has, stored therein, a reference value Src1 of the reflection coefficient rc. The reference value Src1 is set in advance based on an absolute value Arcxy which is calculated by the detection unit 14 when a measurement signal of a specific frequency is outputted to the target transmission line whose bending angle θxy is zero degrees. The reference value Src1 may be set in advance based on a plurality of absolute values Arcxy which are calculated, when measurement signals of a plurality of specific frequencies are outputted to the target transmission line whose bending angle θxy is zero degrees, by the detection unit 14 for the respective frequencies of the measurement signals.

For example, the detection unit 14 calculates the reflection coefficient rc and the absolute value Arc at a calculation timing according to the calculation cycle Cm. Each time the detection unit 14 calculates the absolute value Arc, the detection unit 14 acquires the reference value Src1 from the storage unit 15, and calculates a difference Drc1 by subtracting the reference value Src1 from the absolute value Arc.

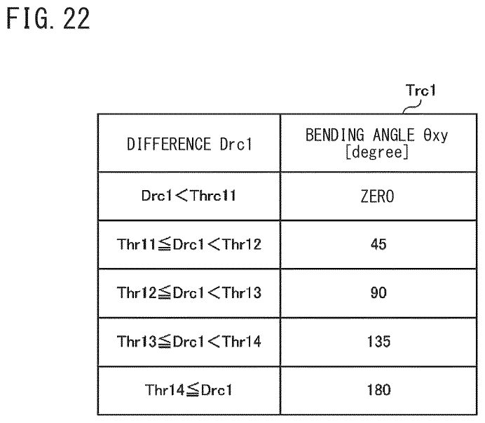

FIG. 22 shows an example of a determination table stored in the storage unit in the detection device according to the first embodiment of the present disclosure. With reference to FIG. 22, the storage unit 15 has, stored therein, a determination table Trc1 indicating the correspondence between the difference Drc1 calculated by the detection unit 14, and the bending angle θxy.

For example, the detection unit 14 detects the bending angle θxy, based on the calculated difference Drc1, and the determination table Trc1 stored in the storage unit 15. More specifically, when the difference Drc1 is less than the threshold value Thr11, the detection unit 14 determines that the bending angle θxy is zero degrees. When the difference Drc1 is equal to or larger than the threshold value Thr11 and less than the threshold value Thr12, the detection unit 14 determines that the bending angle θxy is 45 degrees. When the difference Drc1 is equal to or larger than the threshold value Thr12 and less than the threshold value Thr13, the detection unit 14 determines that the bending angle θxy is 90 degrees. When the difference Drc1 is equal to or larger than the threshold value Thr13 and less than the threshold value Thr14, the detection unit 14 determines that the bending angle θxy is 135 degrees. When the difference Drc1 is equal to or larger than the threshold value Thr14, the detection unit 14 determines that the bending angle θxy is 180 degrees.

For example, the threshold values Thr11, Thr12, Thr13, Thr14 are set in advance based on the above-described absolute values Arcxy_zero, Arcxy_45, Arcxy_90, Arcxy_135, Arcxy_180.

For example, each time the detection unit 14 calculates the difference Drc1, the detection unit 14 accumulates the calculated difference Drc1 in the storage unit 15 to generate time-series data TSD1 of the difference Drc1. Furthermore, for example, each time the detection unit 14 calculates the difference Drc1, the detection unit 14 detects the bending angle θxy, based on the calculated difference Drc1 and the determination table Trc1, and accumulates the detected bending angle θxy in the storage unit 15 to generate time-series data TSDxy of the bending angle θxy.

For example, the detection unit 14 further performs detection of the bending angle θyz and generation of the time-series data TSDxy, based on the reflection coefficient rc, in the same manner as in Detection example 1 and Detection example 2 described above.

Furthermore, for example, the detection unit 14 detects at least one of a change in the bending angle θ of the target transmission line and a change in the curvature of the target transmission line, based on information indicating the initial laying condition of the target transmission line and on the reflection coefficient rc.

### Detection Example 5

### (1) Bending Angle

The detection unit 14 calculates, as an evaluation value EV, an impedance Z of the target transmission line. The detection unit 14 detects a change in the bending angle θ of the target transmission line and a change in the curvature of the target transmission line, based on the calculated impedance Z.

More specifically, the detection unit 14 calculates the impedance Z by performing the process described in Detection example 1.

For example, the storage unit 15 has, stored therein, a reference value SZ of the impedance Z. The reference value SZ is set in advance based on an impedance Z which is calculated by the detection unit 14 when a measurement signal of a specific frequency is outputted to a target transmission line whose bending angles θxy, θyz are zero degrees. The reference value SZ may be set in advance based on a plurality of impedances Z which are calculated, when measurement signals of a plurality of specific frequencies are outputted to the target transmission line whose bending angles θxy, θyz are zero degrees, by the detection unit 14 for the respective frequencies of the measurement signals.

For example, the detection unit 14 calculates the impedance Z at a calculation timing according to the calculation cycle Cm. Each time the detection unit 14 calculates the impedance Z, the detection unit 14 acquires the reference value SZ from the storage unit 15, and calculates a difference DZ by subtracting the reference value SZ from the impedance Z.

For example, the detection unit 14 performs detection of the bending angles θxy, θyz and the curvature of the target transmission line, and generation of time-series data TSDxy, TSDyz, based on the calculated difference DZ.

For example, the storage unit 15 has, stored therein, type information indicating the type of the evaluation value EV to be used when the detection process is performed on the target transmission line. The detection unit 14 calculates the evaluation value EV of the type indicated by the type information stored in the storage unit 15, and detects a change in the level of bending of the target transmission line, based on the calculated evaluation value EV. That is, the detection unit 14 performs any one of Detection examples 1 to 5 described above, according to the type information stored in the storage unit 15, thereby detecting the level of bending of the target transmission line.

The detection unit 14 may calculate a plurality of types of evaluation values EV, and comprehensively evaluate the calculated plurality of types of evaluation values EV to detect a change in the level of bending of the target transmission line. More specifically, for example, the detection unit 14 adopts a detection result in which the change in the level of bending is most remarkable among the detection results based on the plurality of types of evaluation values EV. Alternatively, the detection unit 14 adopts an average value of a plurality of changes in the level of bending based on the plurality of types of evaluation values EV.

### (Counting the Number of Times of Bending)

For example, the detection unit 14 counts the number of times of bending NB of the target transmission line, based on the detection result of the change in the degree of bending of the target transmission line. As an example, the detection unit 14 counts the number of times of bending NB which is the number of times the target transmission line is bent at a bending angle θ equal to or larger than a predetermined value. More specifically, upon detecting a peak value of the difference D in the time-series data TSD1, the detection unit 14 detects the bending angle θ corresponding to the peak value, based on the detected peak value and the determination table stored in the storage unit 15. When the bending angle θ corresponding to the peak value is equal to or larger than the predetermined value, the detection unit 14 increments a count value Vcnt of the number of times of bending NB.

For example, the detection unit 14 weights the count value of the number of times of bending NB, according to the size of the bending angle θ. More specifically, when at least one of the bending angle θxy corresponding to the peak value and the bending angle θyz corresponding to the peak value is equal to or larger than an angle θ1, the detection unit 14 increments by “1” the count value Vcnt of the number of times of bending NB. When at least one of the bending angle θxy corresponding to the peak value and the bending angle θyz corresponding to the peak value is equal to or larger than an angle θ2, the detection unit 14 increments by “2” the count value Vcnt of the number of times of bending NB. Here, it is assumed that the angle θ2 is larger than the angle θ1.

Alternatively, the detection unit 14 individually counts each of a plurality of numbers of times of bending NB, according to the size of the bending angle θ. More specifically, when at least one of the bending angle θxy corresponding to the peak value and the bending angle θyz corresponding to the peak value is equal to or larger than the angle θ1 and less than the angle θ2, the detection unit 14 increments by “1” the count value Vcnt of the number of times of bending NBθ1 which is the number of times of bending NB. When at least one of the bending angle θxy corresponding to the peak value and the bending angle θyz corresponding to the peak value is equal to or larger than the angle θ2, the detection unit 14 increments by “1” the count value Vcnt of the number of times of bending NBθ2 which is the number of times of bending NB.

When the count value Vcnt of the number of times of bending NB exceeds a threshold value Thwrn, the detection unit 14 performs a predetermined notification process. More specifically, when the count value Vcnt of the number of times of bending NB exceeds the threshold value Thwrn, the detection unit 14 performs the notification process of notifying the user of the count result, for example, via a communication unit (not shown) and the communication device 111. Each time the detection unit 14 performs the notification process, the detection unit 14 updates the threshold value Thwrn. More specifically, after the notification process, the detection unit 14 updates the threshold value Thwrn to a value obtained by adding a predetermined value to the count value Vcnt at the time of the notification process.

### [Operation Flow]

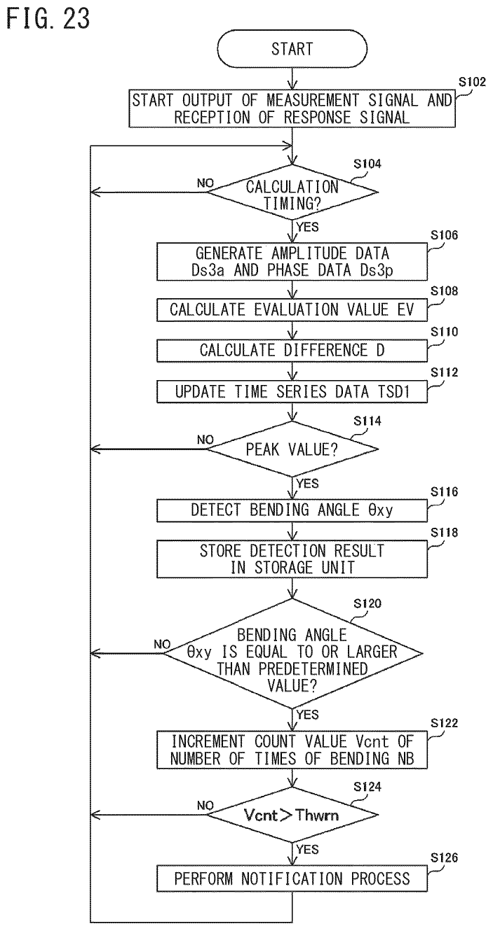

FIG. 23 is a flowchart showing an example of an operation procedure when the relay device according to the first embodiment of the present disclosure performs a detection process.

With reference to FIG. 23, firstly, when the power source of the relay device 101 is turned on, for example, the relay device 101 starts output of a measurement signal and reception of a response signal (step S102).

Next, the relay device 101 waits for a calculation timing for an evaluation value EV (NO in step S104). When the calculation timing has arrived (YES in step S104), the relay device 101 measures an amplitude and a phase of the response signal. More specifically, the relay device 101 generates amplitude data Ds3a indicating the amplitude of the reflection signal included in the response signal, and a phase data Ds3p indicating the phase of the reflection signal (step S106).

Next, the relay device 101 calculates an evaluation value EV, based on amplitude data Ds1a indicating the amplitude of the measurement signal, phase data Ds1p indicating the phase of the measurement signal, the amplitude data Ds3a, and the phase data Ds3p (step S108).

Next, the relay device 101 calculates a difference D between the calculated evaluation value EV and the reference value S of the evaluation value EV (step S110).

Next, the relay device 101 updates the time-series data TSD1 in the storage unit 15, based on the calculated difference D (step S112).

Next, the relay device 101 repeats the processes from step S104 to step S112 until detecting a peak value of the difference D in the time-series data TSD1 (NO in step S114). Upon detecting the peak value of the difference D (YES in step S114), the relay device 101 detects a bending angle θxy corresponding to the peak value, based on the detected peak value and the determination table stored in the storage unit 15 (step S116).

Next, the relay device 101 stores the detection result of the bending angle θxy into the storage unit 15 (step S118).

Next, when the bending angle θxy is less than a predetermined value (NO in step S120), the relay device 101 repeats the processes from step S104 to step S118.

Meanwhile, when the bending angle θxy is equal to or larger than the predetermined value, the relay device 101 increments the count value Vent of the number of times of bending NB (step S122).

Next, when the incremented count value Vcnt is equal to or less than the threshold value Thwrn (NO in step S124), the relay device 101 repeats the processes from step S104 to step S122.

Meanwhile, when the incremented count value Vcnt exceeds the threshold value Thwrn (YES in step S124), the relay device 101 performs a notification process of notifying the user of the count result. Then, the relay device 101 updates the threshold value Thwrn to a value obtained by adding a predetermined value to the current count value Vcnt (step S126).

Next, the relay device 101 repeats the processes from step S104 to step S126.

In step S116, the relay device 101 may detect at least one of the bending angle θxy and the curvature of the target transmission line, in addition to or instead of the bending angle θxy.

In the communication system 301 according to the first embodiment of the present disclosure, the relay device 101 is connected to a communication device 111 on a one-to-one basis via a transmission line 10. However, the present disclosure is not limited thereto. The relay device 101 may be connected to a plurality of communication devices 111 on a one-to-many basis via a bus type transmission line 10.

In the communication system 301 according to the first embodiment of the present disclosure, the relay device 101 performs the detection process. However, the present disclosure is not limited thereto. In the communication system 301, a device other than the relay device 101 may perform the detection process. Specifically, for example, a communication device 111 may function as a detection device to perform the detection process.

In the relay device 101 according to the first embodiment of the present disclosure, the signal output unit 12 outputs a measurement signal, which has a frequency band different from the frequency band of the communication signal transmitted and received by the relay unit 11 via the target transmission line, to the target transmission line during the detection period T1 in which the power source of the relay device 101 is ON. However, the present disclosure is not limited thereto. The signal output unit 12 may output a measurement signal, which has a frequency band including a part or the entirety of the frequency band of the communication signal, to the target transmission line during a period in which the power source of the relay device 101 is ON and the relay unit 11 does not perform the relay process.

In the relay device 101 according to the first embodiment of the present disclosure, the measurement unit 13 receives the response signal, which includes the measurement signal outputted from the signal output unit 12 and the reflection signal that is a signal in which the measurement signal is reflected, from the target transmission line via the corresponding communication port 16. However, the present disclosure is not limited thereto. The measurement unit 13 may receive the response signal that does not include the measurement signal. That is, the measurement unit 13 may receive the reflection signal as the response signal. More specifically, for example, the signal output unit 12 outputs the measurement signal to the target transmission line via a directional coupler and the communication port 16. The measurement unit 13 receives the response signal that does not include the measurement signal, from the target transmission line via the communication port 16 and the directional coupler.

In the relay device 101 according to the first embodiment of the present disclosure, the measurement unit 13 generates the digital signal Ds3 indicating the reflection signal by subtracting the component of the digital signal Ds1 from the digital signal Ds2. However, the present disclosure is not limited thereto. The measurement unit 13 may receive the measurement signal from the signal output unit 12, subtract the component of the measurement signal from the received response signal to generate an analog signal indicating the reflection signal, and convert the generated analog signal into a digital signal to generate the digital signal Ds3.

In the relay device 101 according to the first embodiment of the present disclosure, the detection unit 14 detects a change in the bending angle θ. However, the present disclosure is not limited thereto. For example, the detection unit 14 may detect a change in the bending level indicating the level of bending of the target transmission line, instead of detecting a change in the bending angle θ.

In the relay device 101 according to the first embodiment of the present disclosure, the detection unit 14 stores, in the storage unit 15, the detection result of the change in the bending angle θ and the detection result of the change in the curvature of the target transmission line. However, the present disclosure is not limited thereto. The detection unit 14 may not necessarily store the detection results in the storage unit 15.

In the relay device 101 according to the first embodiment of the present disclosure, the detection unit 14 generates the time-series data TSD1, TSD2, TSDxy, TSDyz. However, the present disclosure is not limited thereto. The detection unit 14 may not necessarily generate the time-series data TSD1, TSD2, TSDxy, TSDyz while counting the number of times of bending NB.

In the relay device 101 according to the first embodiment of the present disclosure, the detection unit 14 counts the number of times of bending NB. However, the present disclosure is not limited thereto. The detection unit 14 may not necessarily count the number of times of bending NB.

In the relay device 101 according to the first embodiment of the present disclosure, when the count value of the number of times of bending NB exceeds the predetermined value, the detection unit 14 performs the notification process. However, the present disclosure is not limited thereto. The detection unit 14 may not necessarily perform the notification process.

Meanwhile, there is a demand for a technology capable of checking the state of the transmission line 10 by using a simple configuration. More specifically, the transmission line 10 may be fatigued and deteriorated when being bent, which may lead to breakage. The transmission line 10 may be bent at a bending angle or a curvature that exceeds flexibility of the transmission line 10, or may be bent for illicit purposes. In order to take an appropriate countermeasure such as warning the user in a situation where the transmission line 10 is not used normally and safely, a technology capable of checking the state of the transmission line 10 is desired.

For example, a technology of detecting the characteristics of the transmission line 10 by using TDR (Time Domain Reflectometry) has been conventionally known. When an attempt is made to detect a change in the characteristics of the transmission line 10 by using such a technology and check the state of the transmission line 10 based on the detection result, it is necessary to output a rising pulse to the transmission line 10 with high reproducibility in order to accurately detect a change in the characteristics of the transmission line 10. As a result, a high performance pulse signal generator is required.

Meanwhile, an attempt is made to measure the characteristics such as an S parameter of the transmission line 10 by using a network analyzer and check the state of the transmission line 10 based on the measurement result, expensive and complex measurement equipment is required in order to ensure sufficient detection accuracy, and furthermore, calibration of the measurement equipment is required for each measurement.

In contrast, in the relay device 101 according to the first embodiment of the present disclosure, the signal output unit 12 outputs a measurement signal having a frequency component to the transmission line 10. The measurement unit 13 receives, from the transmission line 10, the response signal including the signal in which the measurement signal is reflected, and measures at least one of the amplitude and the phase of the received response signal. The detection unit 14 calculates the evaluation value EV based on the measurement result of the measurement unit 13, and detects a change in the level of bending of the transmission line 10, based on a change over time of the calculated evaluation value EV.

As described above, the measurement signal having the frequency component is outputted to the transmission line 10, the evaluation value EV is calculated based on the measurement result of at least one of the amplitude and the phase of the response signal received from the transmission line 10, and a change in the level of bending of the transmission line 10 is detected based on a change over time of the calculated evaluation value EV. In this configuration, a change in the level of bending of the transmission line 10 can be detected without requiring a detection line other than the transmission line 10, and a bending sensor or the like. Therefore, the state of the transmission line 10 can be checked by using a simple configuration.

Next, another embodiment of the present disclosure will be described with reference to the drawings. In the drawings, the same or corresponding parts are denoted by the same reference signs, and descriptions thereof are not repeated.

### Second Embodiment

This embodiment relates to a relay device 102 which detects a change in the level of bending of a detection line 20, instead of the relay device 101 according to the first embodiment. The relay device 102 is identical to the relay device 101 according to the first embodiment except for the details described below.

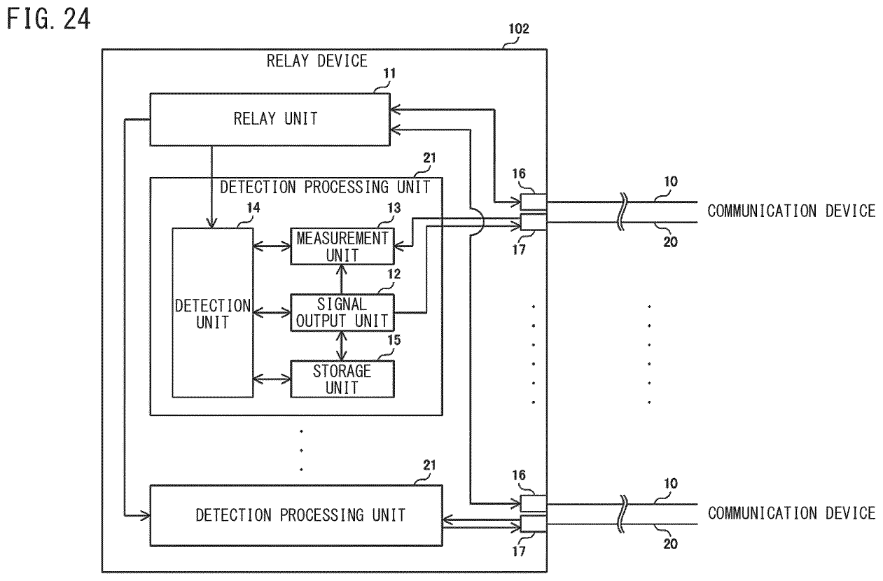

FIG. 24 shows the configuration of the relay device according to the second embodiment of the present disclosure. With reference to FIG. 24, the relay device 102 further includes a plurality of detection ports 17 in contrast to the relay device 101. More specifically, the relay device 102 includes the same number of detection ports 17 as the number of the communication ports 16. A connector part as a first end of the detection line 20 is connected to each detection port 17.

The detection line 20 is provided along the transmission line 10. The detection line 20 may be provided along the transmission line 10 in an area from the first end to the second end of the transmission line 10, or may be provided along the transmission line 10 in a part of the area from the first end to the second end of the transmission line 10.

For example, the detection line 20 is provided inside the sheath 2 of the transmission line 10. Alternatively, the detection line 20 is bundled with the transmission line 10. In this case, for example, the detection line 20 is a dedicated line that is not used for communication.

The second end of the detection line 20 opposite to the first end is open, is connected to a ground node, or is connected to the ground node via a termination circuit. The ground node may be a node in a signal return path, or may be a node in a chassis of a structure such as a vehicle in which the communication system 301 is installed. The termination circuit is, for example, a resistor having a resistance value according to the characteristic impedance of the detection line 20, for matching the terminal ends of the detection line 20. The termination circuit may not necessarily accurately match the terminal ends of the detection line 20. Hereinafter, the detection line 20 whose second end is open is also referred to as “open detection line”. The detection line 20 whose second end is connected to the ground node is also referred to as “short-circuit detection line”. The detection line 20 whose second end is connected to the ground node via the termination circuit is also referred to as “matching detection line”.

In operating the communication system 301, the detection line 20 may be bent in the XY plane or the YZ plane together with the transmission line 10 due to, for example, external force applied thereto. Hereinafter, a bending angle θd of the detection line 20 in the XY plane is referred to as a bending angle θdxy, and a bending angle θd of the detection line 20 in the YZ plane is referred to as a bending angle θdyz. The bending angle θd is an example of the bending angle of the detection line 20.

The relay device 102 outputs a measurement signal having a frequency component to the detection line 20, and receives, from the detection line 20, a response signal including a signal in which the measurement signal is reflected. The relay device 102 measures an amplitude and a phase of the received response signal, and calculates an evaluation value EV based on the measurement result. Then, the relay device 102 detects a change in the level of bending of the detection line 20, based on a change over time of the calculated evaluation value EV. As described above, the detection line 20 is provided along the transmission line 10, and is bent together with the transmission line 10. Therefore, by detecting a change in the level of bending of the detection line 20, the state of the transmission line 10 can be checked. The detection line 20 is an example of a target line.

For example, the relay device 102 includes the same number of detection processing units 21 as the number of the detection ports 17. More specifically, a detection processing unit 21 is provided so as to correspond to a detection port 17, and performs a detection process of detecting a change in the level of bending of the detection line 20 connected to the corresponding detection port 17. Hereinafter, a detection process by one detection processing unit 21 in the relay device 102 will be described as a representative. A detection line 20 to be detected by this detection processing unit 21 is also referred to as “target detection line”.

### Detection Example 6

The detection unit 14 calculates a capacitance C of the target detection line, as an evaluation value EV. For example, the detection unit 14 calculates a capacitance C of the open detection line. Based on the calculated capacitance C, the detection unit 14 detects a bending angle θd of the target detection line and a curvature of the target detection line.

More specifically, the signal output unit 12 outputs the measurement signal to the open detection line as the target detection line, and outputs a digital signal Ds1 corresponding to the outputted measurement signal to the detection unit 14.

Upon receiving the digital signal Ds1 from the signal output unit 12, the detection unit 14 performs the process described in Detection example 1, based on the received digital signal Ds1, thereby calculating an impedance Z.

Hereinafter, the impedance Z of the open detection line is referred to as an impedance Zop. The impedance Zop is represented by the following formula (2).

$$\begin{matrix}[ Math . 2 ] & \\ Zop = \frac{1}{G + j ω C} & ( 2 )\end{matrix}$$

In formula (2), G is the conductance of the target detection line, j is an imaginary unit, and ω is an angular velocity [rad/sec].

After calculating the impedance Zop, the detection unit 14 acquires a capacitance C from an imaginary part of the impedance Zop.

For example, the storage unit 15 has, stored therein, a reference value SC of the capacitance C. The reference value SC is set in advance based on a capacitance C which is calculated by the detection unit 14 when a measurement signal of a specific frequency is outputted to the target detection line whose bending angles θdxy, θdyz are zero degrees. The reference value SC may be set in advance based on a plurality of capacitances C which are calculated, when measurement signals of a plurality of specific frequencies are outputted to the target detection line whose bending angles θdxy, θdyz are zero degrees, by the detection unit 14 for the respective frequencies of the measurement signals.

Each time the detection unit 14 calculates the capacitance C, the detection unit 14 acquires the reference value SC from the storage unit 15, and calculates a difference DC by subtracting the reference value SC from the capacitance C.

For example, based on the calculated difference DC, the detection unit 14 detects a change in the bending angles θdxy, θdyz, and a change in the curvature of the target detection line.

### Detection Example 7

The detection unit 14 calculates an inductance L of the target detection line, as an evaluation value EV. For example, the detection unit 14 calculates an inductance L of the short-circuit detection line. Based on the calculated inductance L, the detection unit 14 detects a bending angle θd and a curvature of the target detection line.

More specifically, the signal output unit 12 outputs the measurement signal to the short-circuit detection line as the target detection line, and outputs a digital signal Ds1 corresponding to the outputted measurement signal to the detection unit 14.

Upon receiving the digital signal Ds1 from the signal output unit 12, the detection unit 14 performs the process described in Detection example 1, based on the received digital signal Ds1, thereby calculating an impedance Z.

Hereinafter, the impedance Z of the short-circuit detection line is referred to as an impedance Zst. The impedance Zst is represented by the following formula (3).

$$\begin{matrix}[ Math . 3 ] & \\ Zst = R + j ω L & ( 3 )\end{matrix}$$

In formula (3), R is a DC resistance [Ω] per unit length of the target detection line.

After calculating the impedance Zst, the detection unit 14 acquires an inductance L from an imaginary part of the impedance Zst.

For example, the storage unit 15 has, stored therein, a reference value SL of the inductance L. The reference value SL is set in advance based on an inductance L which is calculated by the detection unit 14 when a measurement signal of a specific frequency is outputted to the target detection line whose bending angles θdxy, θdyz are zero degrees. The reference value SL may be set in advance based on a plurality of inductances L which are calculated, when measurement signals of a plurality of specific frequencies are outputted to the target detection line whose bending angles θdxy, θdyz are zero degrees, by the detection unit 14 for the respective frequencies of the measurement signals.

Each time the detection unit 14 calculates the inductance L, the detection unit 14 acquires the reference value SL from the storage unit 15, and calculates a difference DL by subtracting the reference value SL from the inductance L.

For example, based on the calculated difference DL, the detection unit 14 detects a change in the bending angles θdxy, θdyz, and a change in the curvature of the target detection line.

### Detection Example 8

The detection unit 14 calculates a characteristic impedance Zc of the target detection line, as an evaluation value EV. Based on the calculated characteristic impedance Zc, the detection unit 14 detects a change in a bending angle θd of the target detection line.

More specifically, with the second end of the target detection line being in the open state, the signal output unit 12 outputs the measurement signal to the target detection line, and outputs a digital signal Ds1 corresponding to the outputted measurement signal to the detection unit 14.

Upon receiving the digital signal Ds1 from the signal output unit 12, the detection unit 14 performs the process described in Detection example 6, based on the received digital signal Ds1, thereby calculating an impedance Zop.

Next, with the second end of the target detection line being connected to the ground node, the signal output unit 12 outputs the measurement signal to the target detection line, and outputs a digital signal Ds1 corresponding to the outputted measurement signal to the detection unit 14.

Upon receiving the digital signal Ds1 from the signal output unit 12, the detection unit 14 performs the process described in Detection example 7, based on the received digital signal Ds1, thereby calculating an impedance Zst. The detection unit 14 may calculate the impedance Zst first, and then calculate the impedance Zop.

Then, the detection unit 14 calculates a characteristic impedance Zc according to the following formula (4).

$$\begin{matrix}[ Math . 4 ] & \\ Zc = \sqrt{Zop \times Zst} & ( 4 )\end{matrix}$$

For example, the storage unit 15 has, stored therein, a reference value SZc of the characteristic impedance Zc. The reference value SZc is set in advance based on a characteristic impedance Zc which is calculated by the detection unit 14 when a measurement signal of a specific frequency is outputted to a target detection line whose bending angles θdxy, θdyz are zero degrees. The reference value SZc may be set in advance based on a plurality of characteristic impedances Zc which are calculated by the detection unit 14 when measurement signals of a plurality of specific frequencies are outputted to the target detection line whose bending angles θdxy, θdyz are zero degrees, for the respective frequencies of the measurement signals.

Each time the detection unit 14 calculates the characteristic impedance Zc, the detection unit 14 acquires the reference value SZc from the storage unit 15, and calculates a difference DZc by subtracting the reference value SZc from the characteristic impedance Zc. For example, based on the calculated difference DZc, the detection unit 14 acquires a change in the bending angles θdxy, θdyz, and a change in the curvature of the target detection line.

The detection unit 14 may calculate a reactance X of the matching detection line, the open detection line, or the short-circuit detection line, and detect a change in the bending angle θd and a change in the curvature of the detection line 20, based on the calculated reactance X.

The detection unit 14 may calculate a resistance R of the matching detection line, the open detection line, or the short-circuit detection line, and detect a change in the bending angle θd and a change in the curvature of the target detection line, based on the calculated resistance R.

The detection unit 14 may calculate a phase difference pd between the measurement signal outputted to the matching detection line, the open detection line, or the short-circuit detection line, and the reflection signal included in the response signal, and detect a change in the bending angle θd and a change in the curvature of the target detection line, based on the calculated phase difference pd.

The detection unit 14 may calculate a reflection coefficient rc between the measurement signal outputted to the matching detection line, the open detection line, or the short-circuit detection line, and the reflection signal included in the response signal, and detect a change in the bending angle θd and a change in the curvature of the target detection line, based on the calculated reflection coefficient rc.

The detection unit 14 may calculate an impedance Z of the matching detection line, the open detection line, or the short-circuit detection line, and detect a change in the bending angle θd and a change in the curvature of the target detection line, based on the calculated impedance Z.

The above embodiments are merely illustrative in all aspects and should not be recognized as being restrictive. The scope of the present disclosure is defined by the scope of the claims rather than by the description above, and is intended to include meaning equivalent to the scope of the claims and all modifications within the scope.

The processes (functions) of the above-described embodiments may be realized by processing circuitry including one or more processors. In addition to the one or more processors, the processing circuitry may include an integrated circuit or the like in which one or more memories, various analog circuits, and various digital circuits are combined. The one or more memories have, stored therein, programs (instructions) that cause the one or more processors to execute the processes. The one or more processors may execute the processes according to the program read out from the one or more memories, or may execute the processes according to a logic circuit designed in advance to execute the processes. The above processors may include a CPU (Central Processing Unit), a GPU (Graphics Processing Unit), a DSP (Digital Signal Processor), an FPGA (Field Programmable Gate Array), an ASIC (Application Specific Integrated Circuit), etc., which are compatible with computer control. The physically separated processors may execute the processes in cooperation with each other. For example, the processors installed in physically separated computers may execute the processes in cooperation with each other through a network such as a LAN (Local Area Network), a WAN (Wide Area Network), or the Internet. The program may be installed in the memory from an external server device or the like through the network. Alternatively, the program may be distributed in a state of being stored in a recording medium such as a CD-ROM (Compact Disc Read Only Memory), a DVD-ROM (Digital Versatile Disk Read Only Memory), or a semiconductor memory, and may be installed in the memory from the recording medium.

The above description includes the features in the additional notes below.

### [Additional Note 1]

A detection device comprising:
a signal output unit configured to output a measurement signal having a frequency component to a target line;
a measurement unit configured to receive, from the target line, a response signal including a signal in which the measurement signal is reflected, and measure at least one of an amplitude and a phase of the received response signal; and
a detection unit configured to calculate an evaluation value based on a measurement result obtained by the measurement unit, and detect a change in a level of bending of the target line, based on a change over time in the calculated evaluation value, wherein
the detection unit detects a change in a bending angle of the target line, and counts the number of times of bending of the target line, based on a detection result of the change in the bending angle, and
the detection unit weights a count value of the number of times of bending according to a size of the bending angle.

### [Additional Note 2]

A detection device comprising processing circuitry,
the processing circuitry being configured to:
output a measurement signal having a frequency component to a target line;
receive, from the target line, a response signal including a signal in which the measurement signal is reflected, and measure at least one of an amplitude and a phase of the received response signal; and
calculate an evaluation value based on a measurement result of at least one of the amplitude and the phase, and detect a change in a level of bending of the target line, based on a change over time in the calculated evaluation value.

### REFERENCE SIGNS LIST

1 core wire
2 sheath
3 strand
4 insulating layer
10 transmission line
20 detection line
11 relay unit
12 signal output unit
13 measurement unit
14 detection unit
15 storage unit
16 communication port
17 detection port
1 detection processing unit
101, 102 relay device
111 communication device
301 communication system
TX1, TX2, TR1, TR2, Tpd1, Trc1 determination table

The invention claimed is:

1. A detection device comprising:
a signal output unit configured to output a measurement signal having a frequency component to a target line;
a measurement unit configured to receive, from the target line, a response signal including a signal in which the measurement signal is reflected, and measure at least one of an amplitude and a phase of the received response signal; and
a detection unit configured to calculate an evaluation value based on a measurement result obtained by the measurement unit, and detect a change in a level of bending of the target line, based on a change over time in the calculated evaluation value.

2. The detection device according to claim 1, wherein the detection unit detects a change in a bending angle of the target line.

3. The detection device according to claim 1, wherein the detection unit detects a change in a curvature of the target line.

4. The detection device according to claim 1, wherein
the target line is a transmission line, and
the detection unit calculates, as the evaluation value, at least one of: a phase difference between the measurement signal and the response signal; a reflection coefficient that is a ratio of an amplitude of the response signal to an amplitude of the measurement signal; an impedance of the transmission line; and a resistance of the transmission line.

5. The detection device according to claim 1, wherein
the target line is a transmission line, and
the detection unit calculates, as the evaluation value, a reactance of the transmission line.

6. The detection device according to claim 1, wherein
the target line is a detection line provided along a transmission line, and
the detection unit calculates, as the evaluation value, at least one of: a capacitance of the detection line, an inductance of the detection line, and a characteristic impedance of the detection line.

7. The detection device according to claim 1, wherein the detection unit counts the number of times of bending of the target line, based on a detection result of the change in the level of bending of the target line.

8. The detection device according to claim 7, wherein the detection unit performs a predetermined notification process when a count value of the number of times of bending exceeds a predetermined value.

9. The detection device according to claim 1, wherein the detection unit stores a detection result of the change in the level of bending of the target line into a storage unit.

10. A detection method in a detection device, comprising:
outputting a measurement signal having a frequency component to a target line;
receiving, from the target line, a response signal including a signal in which the measurement signal is reflected, and measuring at least one of an amplitude and a phase of the received response signal; and
calculating an evaluation value based on a measurement result of at least one of the amplitude and the phase, and detecting a change in a level of bending of the target line, based on a change over time in the calculated evaluation value.
